(19) United States
(12) Patent Application Publication
(10) Pub. No.: US 2026/0068145 A1
(43) Pub. Date: Mar. 5, 2026

(54) SEMICONDUCTOR STRUCTURES AND FABRICATION METHODS THEREOF

(71) Applicant: Yangtze Memory Technologies Holding Co., Ltd., Wuhan (CN)

(72) Inventors: Yi Zhao, Wuhan (CN); Liang Xiao, Wuhan (CN); Lina Miao, Wuhan (CN); Wenbin Zhou, Wuhan (CN); Zongliang Huo, Wuhan (CN)

(73) Assignee: Yangtze Memory Technologies Holding Co., Ltd., Wuhan (CN)

(21) Appl. No.: 18/909,397

(22) Filed: Oct. 8, 2024

Related U.S. Application Data
(63) Continuation of application No. PCT/CN2024/116325, filed on Sep. 2, 2024.

(51) Int. Cl. H10B 12/00; H01L 25/065; H10B 63/10; H10B 80/00

(52) U.S. Cl. CPC H10B 12/50; H10B 63/10; H10B 80/00

(57) ABSTRACT

A semiconductor structure includes a first semiconductor chip and a second semiconductor chip stacking with the first semiconductor chip along a first direction. The first semiconductor chip includes a first memory structure including a first contact structure extending along a first direction, and a first periphery structure disposed on a first substrate, the first periphery structure in contact with the first memory structure and including a second contact structure extending along the first direction. The second semiconductor chip is bonded to the first semiconductor chip through a chip-to-chip bonding layer, and the first contact structure and the second contact structure are coupled through a first coupling layer.

### CROSS-REFERENCE TO RELATED APPLICATIONS

This application is a continuation of International Application No. PCT/CN2024/116325, filed on Sep. 2, 2024, which is hereby incorporated by reference in its entirety.

### BACKGROUND

The present disclosure relates to semiconductor structures and fabrication methods thereof, specifically to memory devices, memory systems, and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A high bandwidth memory (HBM) uses stacked memory devices or memory chips to enable effective data movement and access. While using less power in a smaller form factor, HBM devices can achieve higher bandwidth. HBM devices have been applied to high-performance graphics accelerators, network devices, high-performance data centers, artificial intelligence (AI) and machine learning (ML) training, and various supercomputers.

### SUMMARY

According to one aspect of the present disclosure, a semiconductor structure is disclosed. The semiconductor structure includes a first semiconductor chip and a second semiconductor chip stacking with the first semiconductor chip along a first direction. The first semiconductor chip includes a first memory structure including a first contact structure extending along a first direction, and a first periphery structure disposed on a first substrate, the first periphery structure in contact with the first memory structure and including a second contact structure extending along the first direction. The second semiconductor chip is bonded to the first semiconductor chip through a chip-to-chip bonding layer, and the first contact structure and the second contact structure are coupled through a first coupling layer.

In some implementations, the second semiconductor chip includes a second memory structure including a third contact structure extending along the first direction, and a second periphery structure disposed on a second substrate, the second periphery structure in contact with the second memory structure and including a fourth contact structure extending along the first direction.

In some implementations, the third contact structure and the fourth contact structure are coupled through a second coupling layer.

In some implementations, the chip-to-chip bonding layer includes a first hybrid dielectric-to-dielectric and metal-to-metal bonding layer.

In some implementations, the first hybrid dielectric-to-dielectric and metal-to-metal bonding layer includes a first nitrogen-doped silicon carbide layer and a first metal structure.

In some implementations, the second contact structure and the third contact structure are coupled through the first metal structure, and the first metal structure penetrates the first nitrogen-doped silicon carbide layer.

In some implementations, the second memory structure of the second semiconductor chip is bonded to the first periphery structure of the first semiconductor chip.

In some implementations, the first memory structure and the second memory structure are separated by the first periphery structure.

In some implementations, the second contact structure penetrates the first substrate, and the fourth contact structure penetrates the second substrate.

In some implementations, the first coupling layer includes a second hybrid dielectric-to-dielectric and metal-to-metal bonding layer.

In some implementations, the first contact structure and the second contact structure are in contact through a second metal structure in the second hybrid dielectric-to-dielectric and metal-to-metal bonding layer.

In some implementations, the second coupling layer includes a third hybrid dielectric-to-dielectric and metal-to-metal bonding layer.

In some implementations, the third contact structure and the fourth contact structure are in contact through a third metal structure in the third hybrid dielectric-to-dielectric and metal-to-metal bonding layer.

In some implementations, the semiconductor structure further includes a logic die disposed below the second semiconductor chip configured to control the semiconductor structure.

In some implementations, the logic die includes a fifth contact structure extending along the first direction, and the logic die is bonded to the second semiconductor chip through a fourth hybrid dielectric-to-dielectric and metal-to-metal bonding layer.

In some implementations, the fifth contact structure is in contact with the fourth contact structure through the fourth hybrid dielectric-to-dielectric and metal-to-metal bonding layer.

In some implementations, the semiconductor structure further includes a bonding pad disposed below the logic die in contact with the fifth contact structure.

According to another aspect of the present disclosure, a semiconductor structure is disclosed. The semiconductor structure includes a first semiconductor chip and a second semiconductor chip stacking with the first semiconductor chip along a first direction. The first semiconductor chip includes a first memory structure including a first vertical transistor extending in a first direction and a first storage unit in contact with the first vertical transistor, and a first periphery structure disposed on a first substrate, the first periphery structure in contact with the first memory structure. The second semiconductor chip includes a second memory structure including a second vertical transistor extending in the first direction and a second storage unit in contact with the second vertical transistor, and a second periphery structure disposed on a second substrate, the second periphery structure in contact with the second memory structure. The second semiconductor chip is bonded to the first semiconductor chip through a first hybrid dielectric-to-dielectric and metal-to-metal bonding layer.

In some implementations, the first hybrid dielectric-to-dielectric and metal-to-metal bonding layer includes a first carbon-doped silicon nitride layer and a first metal structure.

In some implementations, the first memory structure includes a first contact structure extending along the first direction, the first periphery structure includes a second contact structure extending along the first direction, and the first contact structure and the second contact structure are coupled through a first coupling layer.

In some implementations, the first coupling layer includes a second hybrid dielectric-to-dielectric and metal-to-metal bonding layer.

In some implementations, the first vertical transistor includes a first terminal and a second terminal, the first storage unit includes a first end coupled to the first terminal of the first vertical transistor, and a bit line is coupled to the second terminal of the vertical transistor.

In some implementations, the first vertical transistor includes a semiconductor body extending in the first direction, and a gate structure coupled to at least one side of the semiconductor body.

In some implementations, the first hybrid dielectric-to-dielectric and metal-to-metal bonding layer includes a dielectric-to-dielectric bonding layer formed by interlaced silicon oxide layers and carbon-doped silicon nitride layers and a metal bonding structure.

In some implementations, the metal bonding structure extends in the interlaced silicon oxide layers and carbon-doped silicon nitride layers along the first direction.

According to one aspect of the present disclosure, a method of forming a semiconductor structure is disclosed. A first semiconductor chip is formed including a first memory structure having a first contact structure extending along a first direction and a first periphery structure having a second contact structure extending along the first direction. A second semiconductor chip is formed including a second memory structure having a third contact structure extending along the first direction and a second periphery structure having a fourth contact structure extending along the first direction. The first semiconductor chip and the second semiconductor chip are bonded through a first hybrid dielectric-to-dielectric and metal-to-metal bonding layer.

In some implementations, the first memory structure having the first contact structure extending along the first direction is formed. The first periphery structure is formed on a first substrate. The first memory structure and the first periphery structure are bonded. The second contact structure is formed in the first periphery structure extending along the first direction.

In some implementations, the second contact structure is formed penetrating the first substrate along the first direction.

In some implementations, the first memory structure and the first periphery structure are bonded through a second hybrid dielectric-to-dielectric and metal-to-metal bonding layer.

In some implementations, the first memory structure having the first contact structure extending along the first direction is formed. The second contact structure is formed in a first substrate extending along the first direction. The first periphery structure is formed on the first substrate. The first memory structure and the first periphery structure are bonded.

In some implementations, a thinning operation is performed on the first substrate to expose the second contact structure.

In some implementations, the first memory structure and the first periphery structure are bonded through a second hybrid dielectric-to-dielectric and metal-to-metal bonding layer.

In some implementations, a first hybrid bonding interface is formed on the first semiconductor chip. A second hybrid bonding interface is formed on the second semiconductor chip. The first hybrid bonding interface is bonded with the second hybrid bonding interface.

In some implementations, a first carbon-doped silicon nitride layer is formed under the first periphery structure. A first metal structure is formed in the first carbon-doped silicon nitride layer in contact with the second contact structure.

In some implementations, a second carbon-doped silicon nitride layer is formed on the second memory structure. A second metal structure is formed in the second carbon-doped silicon nitride layer in contact with the third contact structure.

In some implementations, the first carbon-doped silicon nitride layer is bonded with the second carbon-doped silicon nitride layer. The first metal structure is bonded with the second metal structure.

### BRIEF DESCRIPTION OF THE DRAWINGS

The accompanying drawings, which are incorporated herein and form a part of the specification, illustrate implementations of the present disclosure and, together with the description, further serve to explain the present disclosure and to enable a person skilled in the pertinent art to make and use the present disclosure.

FIG. 1 illustrates a schematic view of a cross-section of a semiconductor structure, according to some implementations of the present disclosure.

FIG. 2 illustrates a schematic diagram of a memory device including peripheral circuits and an array of memory cells each having a vertical transistor, according to some aspects of the present disclosure.

FIG. 3 illustrates a schematic circuit diagram of a memory device including peripheral circuits and an array of dynamic random-access memory (DRAM) cells, according to some aspects of the present disclosure.

FIG. 4 illustrates a schematic circuit diagram of a memory device including peripheral circuits and an array of phase-change memory (PCM) cells, according to some aspects of the present disclosure.

FIG. 5 illustrates a schematic view of a cross-section of a semiconductor structure, according to some implementations of the present disclosure.

FIGS. 6-33 illustrate cross-sectional views of an exemplary semiconductor structure at various stages of a fabrication process, according to some implementations of the present disclosure.

FIG. 34 illustrates a flowchart of a method for forming an exemplary semiconductor structure, according to some implementations of the present disclosure.

FIG. 35 illustrates a schematic side view of a cross-section of a semiconductor device, according to some implementations of the present disclosure.

FIG. 36 illustrates a schematic side view of a cross-section of a memory system, according to some implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

Implementations of the present disclosure can provide one or more of the following technical advantages and/or benefits. For example, a semiconductor device or a semiconductor structure can include multiple memory dice or memory chips stacked in the vertical direction. The multiple memory chips are bonded together using a direct bonding technology. In some implementations, the HBM may use the through silicon via (TSV) and u-bump technology to achieve die-to-wafer bonding or die-to-die bonding. However, the thickness of a single die is thicker, e.g., about 60 μm, which is not conducive to stacking more layers. In addition, due to the thickness of the die and the large size of the u-bump, the pitch required for TSV is large, and it occupies about 10% of the die area, pushing up its cost.

To address one or more of the aforementioned issues, the present disclosure introduces a semiconductor structure based on vertical transistors. The TSVs are embedded in the array wafer. By thinning the backside of the CMOS wafer, the TSVs could be drawn out to form a connection path that vertically runs through the stack of memory chips. In addition, the present disclosure can also realize power supply from the backside of the CMOS wafer, improving power supply efficiency and reducing IR delay. Since the substrate of the vertical transistors array only has a supporting function, it is easier to thin during the process of stacking multiple memory chips, which is beneficial to maintaining the flatness of the chips, reducing the total thickness of the device, and making it easier to stack a higher number of layers.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

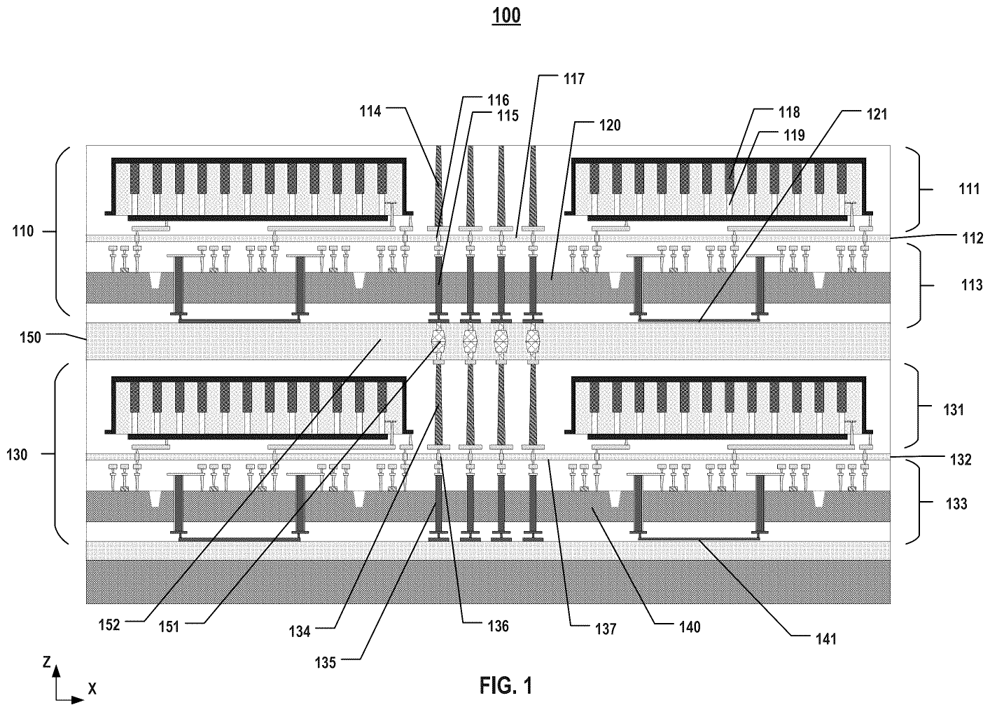

FIG. 1 illustrates a schematic view of a cross-section of a semiconductor structure 100, according to some implementations of the present disclosure. The semiconductor structure 100 includes a first semiconductor chip 110 and a second semiconductor chip 130, stacking with the first semiconductor chip 110 along the Z-direction. In some implementations, the first semiconductor chip 110 and the second semiconductor chip 130 are bonded through a chip-to-chip bonding layer 150.

The first semiconductor chip 110 includes a first memory structure 111 having a first contact structure 114 extending along the Z-direction. The first semiconductor chip 110 further includes a first periphery structure 113 disposed on a first substrate 120. In some implementations, the first memory structure 111 and the first periphery structure 113 are bonded through a first coupling layer 112. The first periphery structure 113 is in contact with the first memory structure 111 through the first coupling layer 112, and the first periphery structure 113 includes a second contact structure 115 extending along the Z-direction. The first contact structure 114 and the second contact structure 115 are coupled through the first coupling layer 112.

In some implementations, the first coupling layer 112 includes a hybrid dielectric-to-dielectric bonding and metal-to-metal bonding layer. In some implementations, the first coupling layer 112 includes a metal structure 116 and a dielectric bonding material 117. In some implementations, the first contact structure 114, the second contact structure 115, and the metal structure 116 include a conductive material, e.g., Cu or W. In some implementations, the dielectric bonding material 117 includes a dielectric bonding material, e.g., nitrogen-doped silicon carbide (NDC).

In some implementations, the first periphery structure 113 includes a backside wiring structure 121. It is understood that the periphery devices, e.g., CMOS, are formed on one side of the first substrate 120, and the backside wiring structure 121 is formed on the opposite side of the first substrate 120, so that the power supply efficiency can be improved and the IR delay can be reduced.

In some implementations, the first memory structure 111 may be a DRAM. In some implementations, the first memory structure 111 may include a capacitor 118 and a vertical transistor 119 extending along the Z-direction.

The second semiconductor chip 130 includes a second memory structure 131 having a third contact structure 134 extending along the Z-direction. The second semiconductor chip 130 further includes a second periphery structure 133 disposed on a second substrate 140. In some implementations, the second memory structure 131 and the second periphery structure 133 are bonded through a second coupling layer 132. The second periphery structure 133 is in contact with the second memory structure 131 through the second coupling layer 132, and the second periphery structure 133 includes a fourth contact structure 135 extending along the Z-direction. The third contact structure 134 and the fourth contact structure 135 are coupled through the second coupling layer 132.

In some implementations, the second coupling layer 132 includes a hybrid dielectric-to-dielectric bonding and metal-to-metal bonding layer. In some implementations, the second coupling layer 132 includes a metal structure 136 and a dielectric bonding material 137. In some implementations, the third contact structure 134, the fourth contact structure 135, and the metal structure 136 include a conductive material, e.g., Cu or W. In some implementations, the dielectric bonding material 137 includes a dielectric bonding material, e.g., nitrogen-doped silicon carbide (NDC).

In some implementations, the second periphery structure 133 includes a backside wiring structure 141. It is understood that the periphery devices, e.g., CMOS, are formed on one side of the second substrate 140, and the backside wiring structure 141 is formed on the opposite side of the second substrate 140, so that the power supply efficiency can be improved and the IR delay can be reduced.

As shown in FIG. 1, the first semiconductor chip 110 and the second semiconductor chip 130 are bonded through a chip-to-chip bonding layer 150. The chip-to-chip bonding layer 150 includes a hybrid dielectric-to-dielectric and metal-to-metal bonding layer. In some implementations, the chip-to-chip bonding layer 150 includes a metal structure 151 and a dielectric bonding material 152. In some implementations, the metal structure 151 includes a conductive material, e.g., Cu or W. In some implementations, the dielectric bonding material 152 includes a dielectric bonding material, e.g., nitrogen-doped silicon carbide (NDC). The second contact structure 115 and the third contact structure 134 are coupled through the metal structure 151 along the Z-direction, and the metal structure 151 penetrates the dielectric bonding material 152, e.g., the nitrogen-doped silicon carbide (NDC) layer. In some implementations, the metal structure 151 extends along the z-direction in the dielectric bonding material 152.

In some implementations, the second memory structure 131 of the second semiconductor chip 130 is bonded to the first periphery structure 113 of the first semiconductor chip 110. In other words, the first memory structure 111 and the second memory structure 131 are separated by the first periphery structure 113. In some implementations, the second contact structure 115 penetrates the first substrate 120, and the fourth contact structure 135 penetrates the second substrate 140.

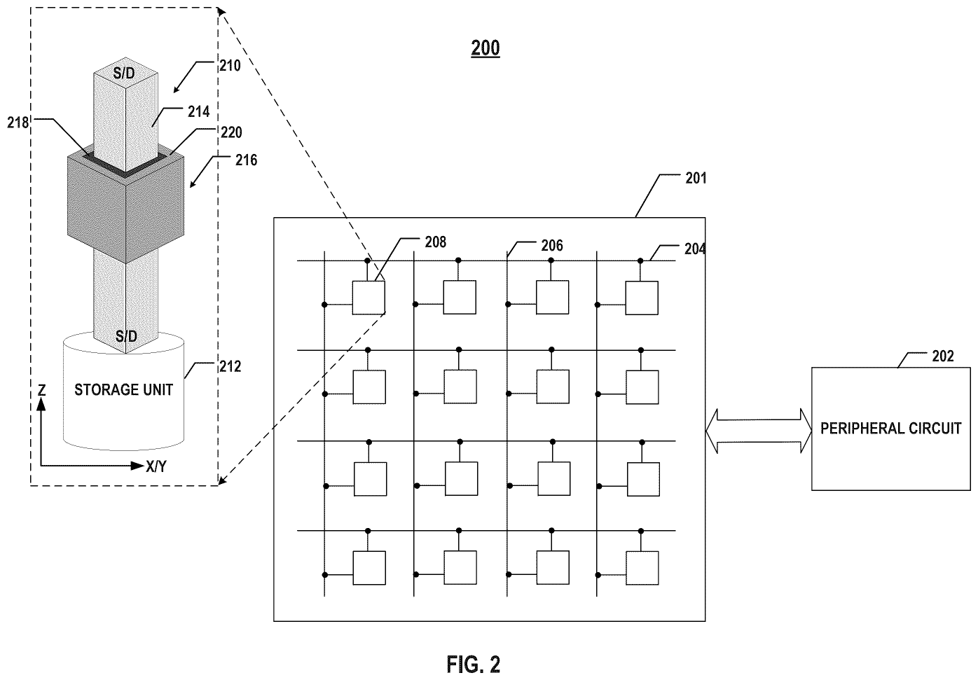

FIG. 2 illustrates a schematic diagram of a memory device 200 including peripheral circuits and an array of memory cells each having a vertical transistor, according to some aspects of the present disclosure. Memory device 200 can include a memory cell array 201 and peripheral circuits 202 coupled to memory cell array 201. The first semiconductor chip 110 and the second semiconductor chip 130 may be examples of memory device 200 in which the first memory structure 111 and/or the second memory structure 131 may be the memory cell array 201, and the first periphery structure 113 and/or the second periphery structure 133 may be the peripheral circuits 202.

The memory cell array 201 can be any suitable memory cell array in which each memory cell 208 includes a vertical transistor 210, e.g., the vertical transistor 119 in FIG. 1, and a storage unit 212, e.g., the capacitor 118 in FIG. 1, coupled to vertical transistor 210. In some implementations, memory cell array 201 is a DRAM cell array, and storage unit 212 is a capacitor for storing charge as the binary information stored by the respective DRAM cell. In some implementations, memory cell array 201 is a PCM cell array, and storage unit 212 is a PCM element (e.g., including chalcogenide alloys) for storing binary information of the respective PCM cell based on the different resistivities of the PCM element in the amorphous phase and the crystalline phase. In some implementations, memory cell array 201 is a FRAM cell array, and storage unit 212 is a ferroelectric capacitor for storing binary information of the respective FRAM cell based on the switch between two polarization states of ferroelectric materials under an external electric field.

As shown in FIG. 2, memory cells 208 can be arranged in a two-dimensional (2D) array having rows and columns. Memory device 200 can include word lines 204 coupling peripheral circuits 202 and memory cell array 201 for controlling the switch of vertical transistors 210 in memory cells 208 located in a row, as well as bit lines 206 coupling peripheral circuits 202 and memory cell array 201 for sending data to and/or receiving data from memory cells 208 located in a column. That is, each word line 204 is coupled to a respective row of memory cells 208, and each bit line is coupled to a respective column of memory cells 208.

Consistent with the scope of the present disclosure, vertical transistors 210, such as vertical metal-oxide-semiconductor field-effect transistors (MOSFETs), can replace the planar transistors as the pass transistors of memory cells 208 to reduce the area occupied by the pass transistors, the coupling capacitance, as well as the interconnect routing complexity, as described below in detail. As shown in FIG. 2, in some implementations, different from planar transistors in which the active regions are formed in the substrates, vertical transistor 210 includes a semiconductor body 214 extending vertically (in the Z-direction) above the substrate (not shown). That is, semiconductor body 214 can extend above the top surface of the substrate to allow channels to be formed not only at the top surface of semiconductor body 214, but also at one or more side surfaces thereof. As shown in FIG. 2, for example, semiconductor body 214 can have a cuboid shape to expose four sides thereof. It is understood that semiconductor body 214 may have any suitable 3D shape, such as a polyhedron shape or a cylinder shape. That is, the cross-section of semiconductor body 214 in the plan view (e.g., in the X-Y plane) can have a square shape, a rectangular shape (or a trapezoidal shape), a circular (or an oval shape), or any other suitable shapes. It is understood that consistent with the scope of the present disclosure, for semiconductor bodies that have a circular or oval shape of their cross-sections in the plan view, the semiconductor bodies may still be considered as having multiple sides, such that the gate structures are in contact with more than one side of the semiconductor bodies. As described below with respect to the fabrication process, semiconductor body 214 can be formed from the substrate (e.g., by etching or epitaxy) and thus, has the same semiconductor material (e.g., silicon crystalline silicon) as the substrate (e.g., a silicon substrate).

As shown in FIG. 2, vertical transistor 210 can also include a gate structure 216 in contact with one or more sides of semiconductor body 214, e.g., in one or more planes of the side surface(s) of the active region. In other words, the active region of vertical transistor 210, e.g., semiconductor body 214, can be at least partially surrounded by gate structure 216. Gate structure 216 can include a gate dielectric 218 over one or more sides of semiconductor body 214, e.g., in contact with four side surfaces of semiconductor body 214, as shown in FIG. 2. Gate structure 216 can also include a gate electrode 220 over and in contact with gate dielectric 218. Gate dielectric 218 can include any suitable dielectric materials, such as silicon oxide, silicon nitride, silicon oxynitride, or high-k dielectrics. For example, gate dielectric 218 may include silicon oxide, which is a form of gate oxide. Gate electrode 220 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 220 may include doped polysilicon, which is a form of a gate poly. In some implementations, gate electrode 220 includes multiple conductive layers, such as a W layer over a TiN layer. It is understood that gate electrode 220 and word line 204 may be a continuous conductive structure in some examples. In other words, gate electrode 220 may be viewed as part of word line 204 that forms gate structure 216, or word line 204 may be viewed as the extension of gate electrode 220 to be coupled to peripheral circuits 202.

As shown in FIG. 2, vertical transistor 210 can further include a pair of a source and a drain (S/D, dope regions, a.k.a., source electrode and drain electrode) formed at the two ends of semiconductor body 214 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 216 in the vertical direction (the z-direction). In other words, gate structure 216 is formed vertically between the source and drain. As a result, one or more channels (not shown) of vertical transistor 210 can be formed in semiconductor body 214 vertically between the source and drain when a gate voltage applied to gate electrode 220 of gate structure 216 is above the threshold voltage of vertical transistor 210. That is, each channel of vertical transistors 210 is also formed in the vertical direction along which semiconductor body 214 extends, according to some implementations.

In some implementations, as shown in FIG. 2, vertical transistor 210 is a multi-gate transistor. That is, gate structure 216 can be in contact with more than one side of semiconductor body 214 (e.g., four sides in FIG. 2) to form more than one gate, such that more than one channel can be formed between the source and drain in operation. That is, different from the planar transistor that includes only a single planar gate (and resulting in a single planar channel), vertical transistor 210 shown in FIG. 2 can include multiple vertical gates on multiple sides of semiconductor body 214 due to the 3D structure of semiconductor body 214 and gate structure 216 that surrounds the multiple sides of semiconductor body 214. As a result, compared with planar transistors, vertical transistor 210 shown in FIG. 2 can have a larger gate control area to achieve better channel control with a smaller subthreshold swing. Since the channel is fully depleted, the leakage current (Ioff) of vertical transistor 210 can be significantly reduced as well. As described below in detail, the multi-gate vertical transistors can include double-gate vertical transistors (e.g., dual-side gate vertical transistors), tri-gate vertical transistors (e.g., tri-side gate vertical transistors), and GAA vertical transistors.

It is understood that although vertical transistor 210 is shown as a multi-gate transistor in FIG. 2, the vertical transistors disclosed herein may also include single-gate transistors as described below in detail. That is, gate structure 216 may be in contact with a single side of semiconductor body 214, for example, for the purpose of increasing the transistor and memory cell density. It is also understood that although gate dielectric 218 is shown as being separate (a separate structure) from other gate dielectrics of adjacent vertical transistors (not shown), gate dielectric 218 may be part of a continuous dielectric layer having multiple gate dielectrics of vertical transistors.

In planar transistors and some lateral multiple-gate transistors (e.g., FinFET), the active regions, such as semiconductor bodies (e.g., Fins), extend laterally (in the X-Y plane), and the source and the drain are disposed at different locations in the same lateral plane (the X-Y plane). In contrast, in vertical transistor 210, semiconductor body 214 extends vertically (in the Z-direction), and the source and the drain are disposed in the different lateral planes, according to some implementations. In some implementations, the source and the drain are formed at two ends of semiconductor body 214 in the vertical direction (the Z-direction), respectively, thereby being overlapped in the plan view. As a result, the area (in the X-Y plane) occupied by vertical transistor 210 can be reduced compared with planar transistors and lateral multiple-gate transistors. Also, the metal wiring coupled to vertical transistors 210 can be simplified as well since the interconnects can be routed in different planes. For example, bit lines 206 and storage units 212 may be formed on opposite sides of vertical transistor 210. In one example, bit line 206 may be coupled to the source or the drain at the upper end of semiconductor body 214, while storage unit 212 may be coupled to the other source or the drain at the lower end of semiconductor body 214.

As shown in FIG. 2, storage unit 212 can be coupled to the source or the drain of vertical transistor 210. Storage unit 212 can include any devices that are capable of storing binary data (e.g., 0 and 1), including but not limited to, capacitors for DRAM cells and FRAM cells, and PCM elements for PCM cells. In some implementations, vertical transistor 210 controls the selection and/or the state switch of the respective storage unit 212 coupled to vertical transistor 210.

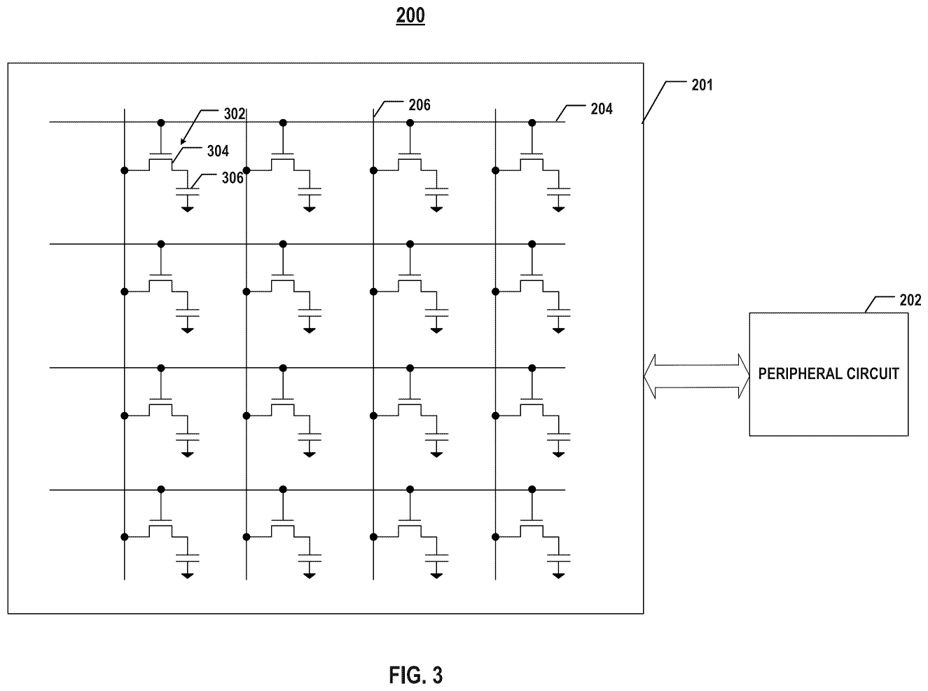

FIG. 3 illustrates a schematic diagram of memory device 200 including peripheral circuits and an array of memory cells each having a vertical transistor, according to some aspects of the present disclosure. In some implementations as shown in FIG. 3, each memory cell 208 is a DRAM cell 302 including a transistor 304 (e.g., implementing using vertical transistors 210 in FIG. 2) and a capacitor 306 (e.g., an example of storage unit 212 in FIG. 2). The gate of transistor 304 (e.g., corresponding to gate electrode 220) may be coupled to word line 204, one of the source and the drain of transistor 304 may be coupled to bit line 206, the other one of the source and the drain of transistor 304 may be coupled to one electrode of capacitor 306, and the other electrode of capacitor 306 may be coupled to the ground.

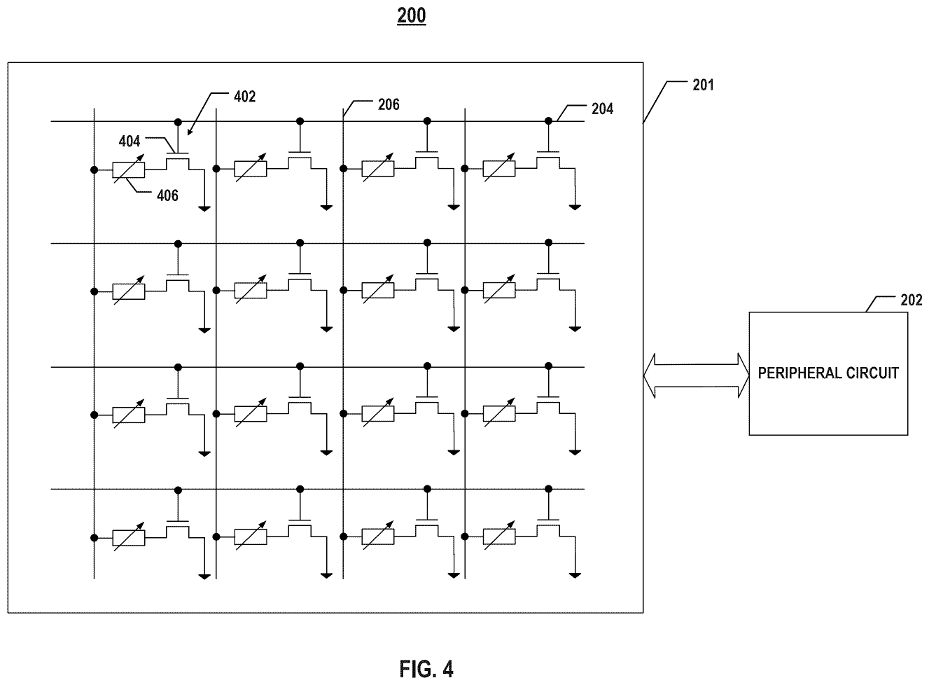

FIG. 4 illustrates a schematic diagram of memory device 200 including peripheral circuits and an array of memory cells each having a vertical transistor, according to some aspects of the present disclosure. In some implementations as shown in FIG. 4, each memory cell 208 is a PCM cell 402 including a transistor 404 (e.g., implementing using vertical transistors 210 in FIG. 2) and a PCM element 406 (e.g., an example of storage unit 212 in FIG. 2). The gate of transistor 404 (e.g., corresponding to gate electrode 220) may be coupled to word line 204, one of the source and the drain of transistor 404 may be coupled to the ground, the other one of the source and the drain of transistor 404 may be coupled to one electrode of PCM element 406, and the other electrode of PCM element 406 may be coupled to bit line 206.

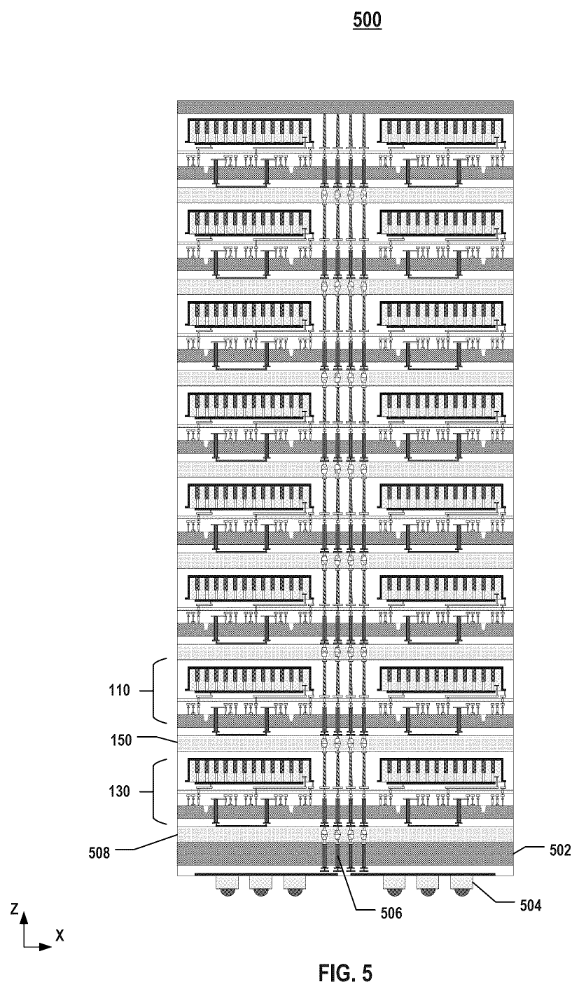

FIG. 5 illustrates a schematic view of a cross-section of a semiconductor structure 500, according to some implementations of the present disclosure. In some implementations, the first semiconductor chip 110 and the second semiconductor chip 130 in FIG. 5 may have the same structure as the first semiconductor chip 110 and the second semiconductor chip 130 in FIG. 1. A logic die 502 is disposed below the second semiconductor chip 130, and the logic die 502 is configured to control the semiconductor structure 500. It is understood that the stacking layers of the first semiconductor chip 110 and the second semiconductor chip 130 may be adjusted according to the manufacturing process or the product requirements, and the layers of the memory stack are not limited here.

In some implementations, the logic die 502 includes a fifth contact structure 506 extending along the Z-direction, and the logic die 502 is bonded to the second semiconductor chip 130 through a hybrid dielectric-to-dielectric and metal-to-metal bonding layer 508. The fifth contact structure 506 is in contact with the fourth contact structure 135 through the hybrid dielectric-to-dielectric and metal-to-metal bonding layer 508. In some implementations, a bonding pad 504 is disposed below the logic die 502 in contact with the fifth contact structure 506.

By forming the first contact structure 114 and/or the third contact structure 134 in the array wafer, forming the second contact structure 115 and/or the fourth contact structure 135 in the CMOS wafer, and thinning the backside of the CMOS wafer, the TSVs could be drawn out to form a connection path that vertically runs through the stack of memory chips. In addition, the present disclosure can also realize power supply from the backside of the CMOS wafer, improving power supply efficiency and reducing IR delay. Since the substrate of the vertical transistors array only has a supporting function, it is easier to thin during the process of stacking multiple memory chips, which is beneficial to maintaining the flatness of the chips, reducing the total thickness of the device, and making it easier to stack a higher number of layers.

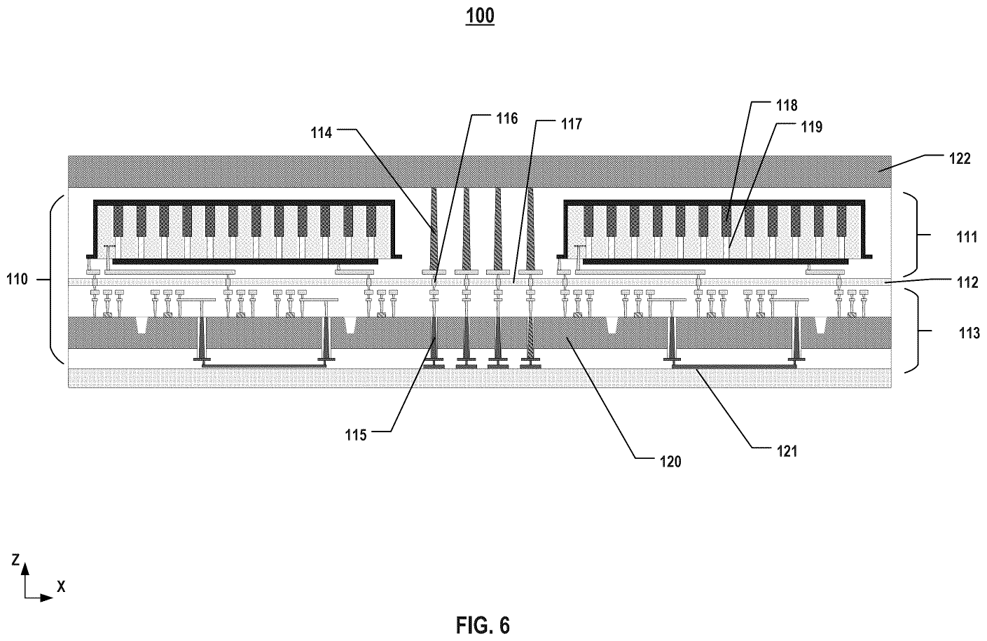

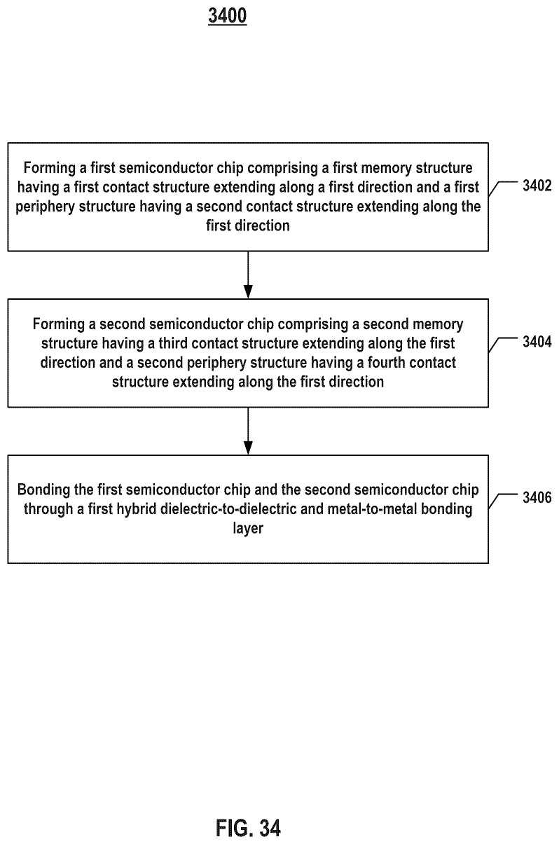

FIGS. 6-33 illustrate cross-sectional views of the semiconductor structure 100 at various stages of a fabrication process, according to some implementations of the present disclosure. FIG. 34 illustrates a flowchart of a method 3400 for forming the semiconductor structure 100, according to some implementations of the present disclosure. For the purpose of better describing the present disclosure, the semiconductor structure 100 in FIGS. 6-33 and method 3400 in FIG. 34 will be discussed together. It is understood that the operations shown in method 3400 are not exhaustive and that other operations may be performed as well before, after, or between any of the illustrated operations. Further, some of the operations may be performed simultaneously, or in a different order than shown in FIGS. 6-33 and FIG. 34.

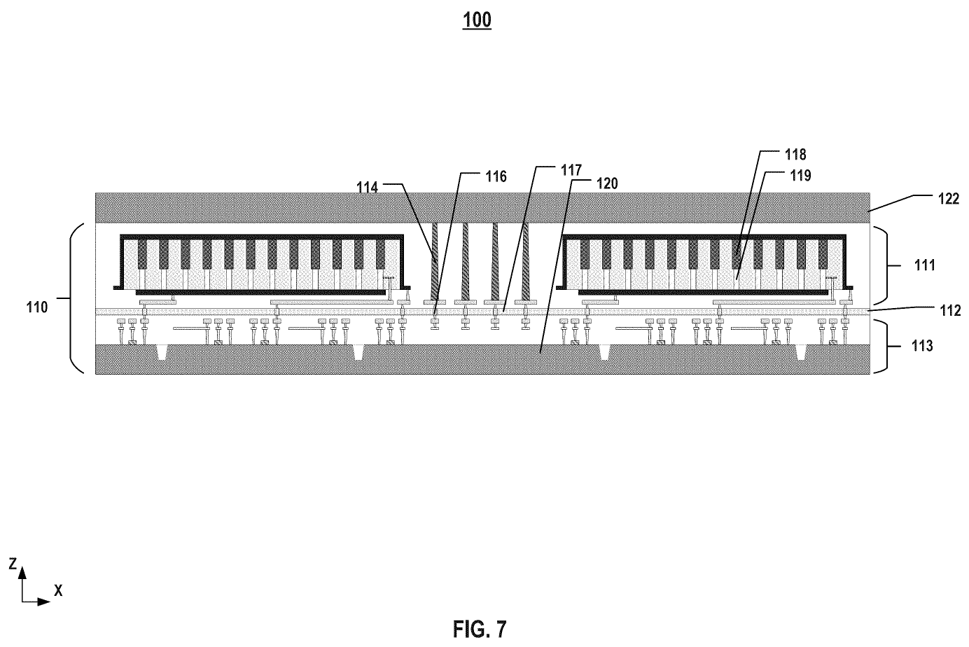

As shown in FIG. 6 and operation 3402 of FIG. 34, the first semiconductor chip 110 is formed. The first semiconductor chip 110 includes the first memory structure 111 having the first contact structure 114 extending along the Z-direction and the first periphery structure 113 having the second contact structure 115 extending along the Z-direction. For forming the first semiconductor chip 110, in some implementations, as shown in FIG. 7, operation 3402 may include forming the first memory structure 111 having the first contact structure 114 extending along the Z-direction, forming the first periphery structure 113 on the first substrate 120, and bonding the first memory structure 111 and the first periphery structure 113. Then, the second contact structure 115 is formed in the first periphery structure 113 extending along the Z-direction.

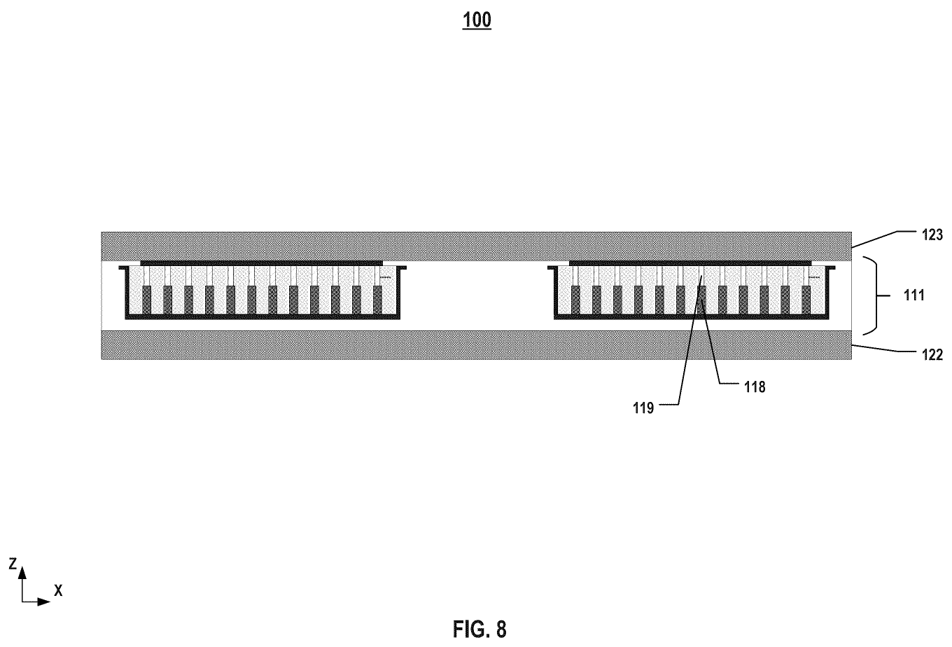

As shown in FIG. 8, the first memory structure 111 is formed on an array substrate 123, and the first memory structure 111 and the array substrate 123 are flipped over to mount on the carrier substrate 122. In some implementations, the first memory structure 111 may be a DRAM. In some implementations, the first memory structure 111 may include the capacitor 118 and the vertical transistor 119 extending along the Z-direction.

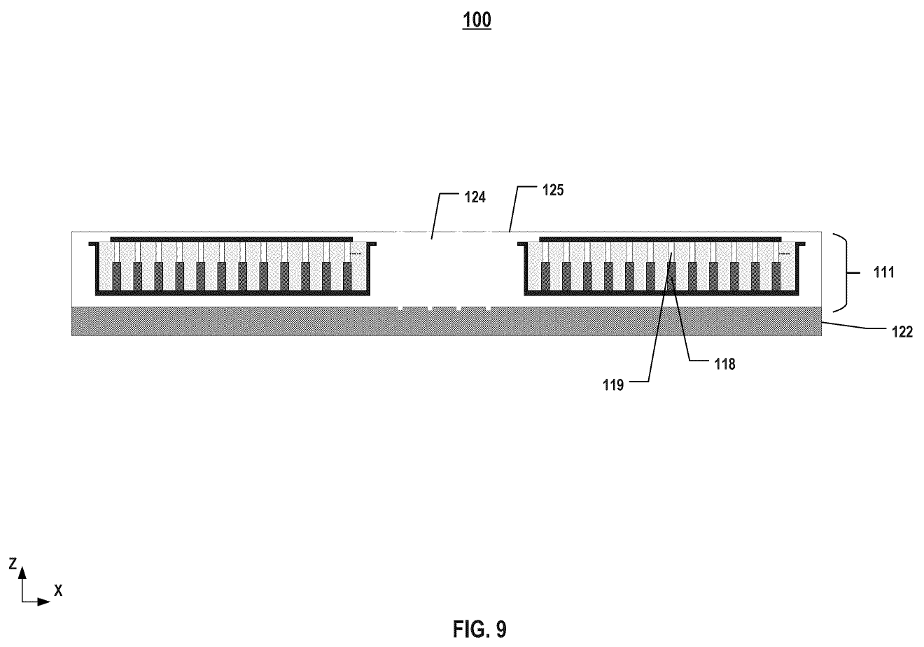

As shown in FIG. 9, the array substrate 123 is removed and a contact hole 124 is formed in the dielectric layer 125 extending along the Z-direction. In some implementations, before performing the etching operation for forming the contact hole 124, a deposition operation may be further performed to increase the thickness of the dielectric layer 125. In some implementations, the dielectric layer 125 includes silicon oxide. In some implementations, the contact hole 124 penetrates the dielectric layer 125 and exposes the carrier substrate 122. In some implementations, the contact hole 124 penetrates the dielectric layer 125 and extends into the carrier substrate 122, as shown in FIG. 9.

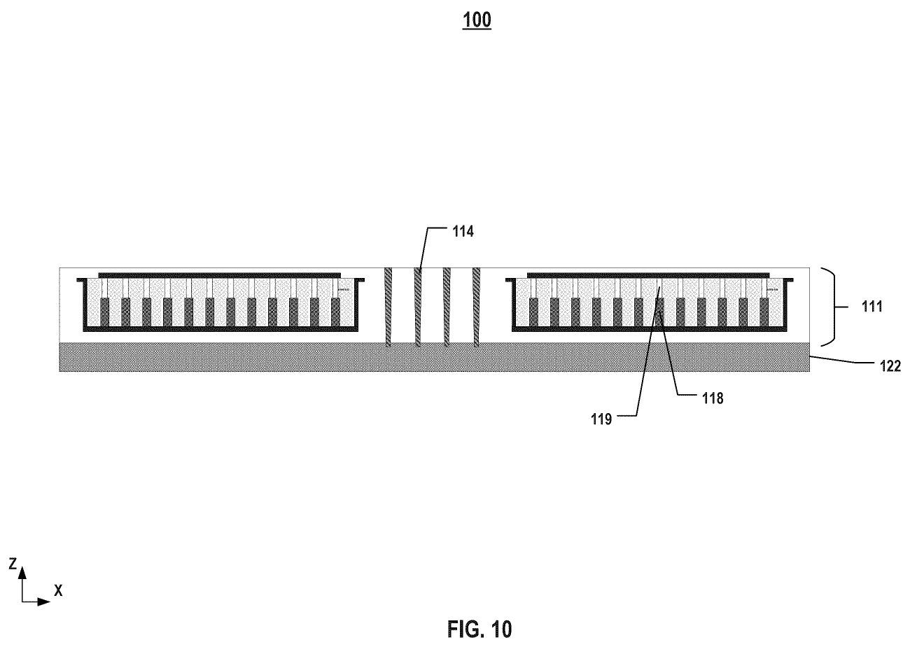

As shown in FIG. 10, the first contact structure 114 is formed in the contact hole 124. In some implementations, the first contact structure 114 includes a conductive material, e.g., Cu or W. In some implementations, the first contact structure 114 extends along the Z-direction in the first memory structure 111 and further extends into the carrier substrate 122. In some implementations, a planarization operation may be further performed on the first memory structure 111 after forming the first contact structure 114.

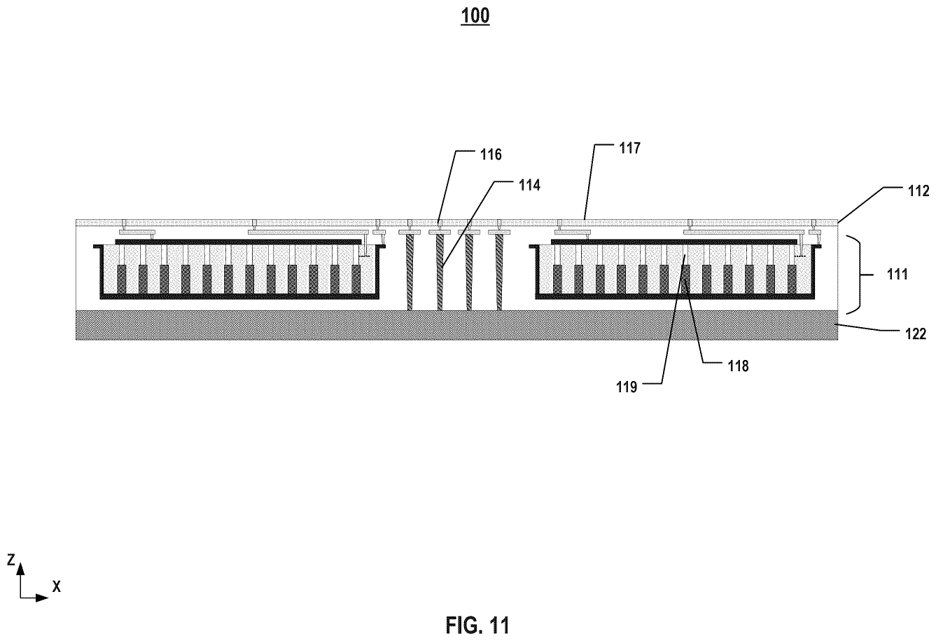

Then, as shown in FIG. 11, the redistribution structure may be formed on the first memory structure 111 to connect the wirings of the first contact structure 114, and the terminals of the capacitor 118 and the vertical transistor 119. Then, the first coupling layer 112 is formed on the redistribution structure. The first coupling layer 112 includes the metal structure 116 in contact with at least the first contact structure 114 and the dielectric bonding material 117. In some implementations, the first contact structure 114 and the metal structure 116 include a conductive material, e.g., Cu or W. In some implementations, the dielectric bonding material 117 includes a dielectric bonding material, e.g., nitrogen-doped silicon carbide (NDC).

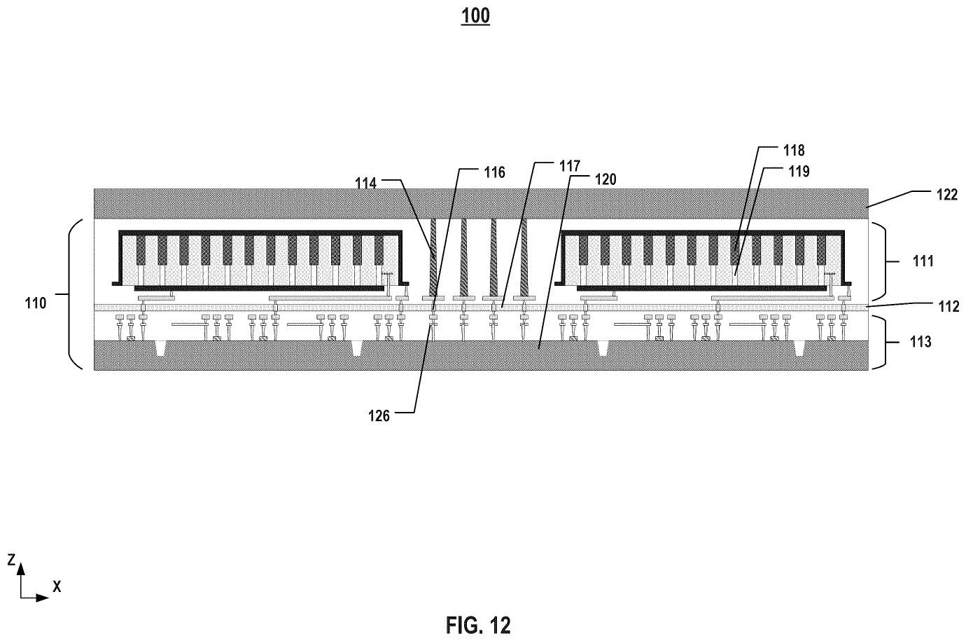

As shown in FIG. 12, the first memory structure 111 and the carrier substrate 122 are flipped over and are bonded to the first periphery structure 113 through the first coupling layer 112. In some implementations, the periphery devices, e.g., CMOS, are formed on one side of the first substrate 120, and the redistribution structures 126 are formed on the periphery devices. The first periphery structure 113 is boned to the first memory structure 111 through the first coupling layer 112.

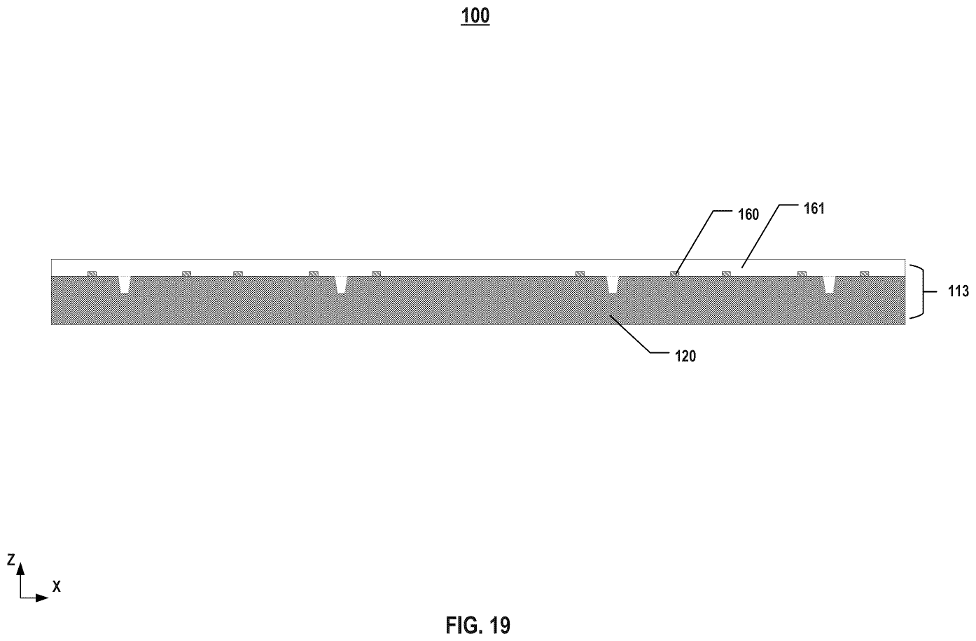

It is noted here that the second contact structure 115 may be formed in the first periphery structure 113 after the bonding of the first memory structure 111 and the first periphery structure 113, as shown in FIGS. 12-18. In other implementations, the second contact structure 115 may be formed in the first periphery structure 113 before the bonding of the first memory structure 111 and the first periphery structure 113, as shown in FIGS. 19-26.

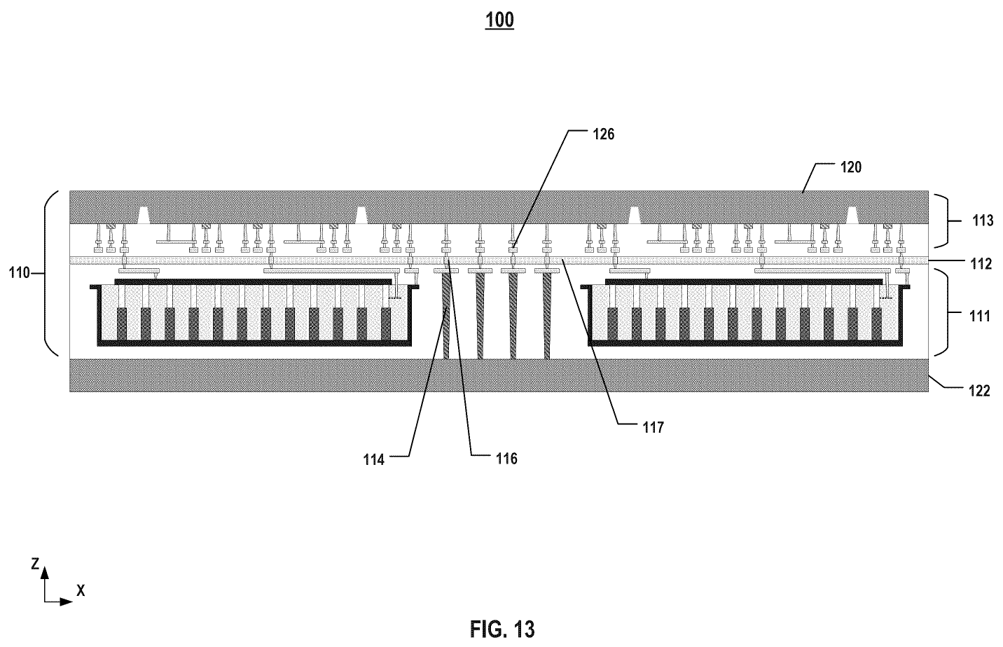

As shown in FIG. 13, after the bonding of the first memory structure 111 and the first periphery structure 113, the structure is flipped over to perform operations on the backside of the first substrate 120. In some implementations, a thinning operation is performed on the backside of the first substrate 120 to reduce the thickness of the first substrate 120.

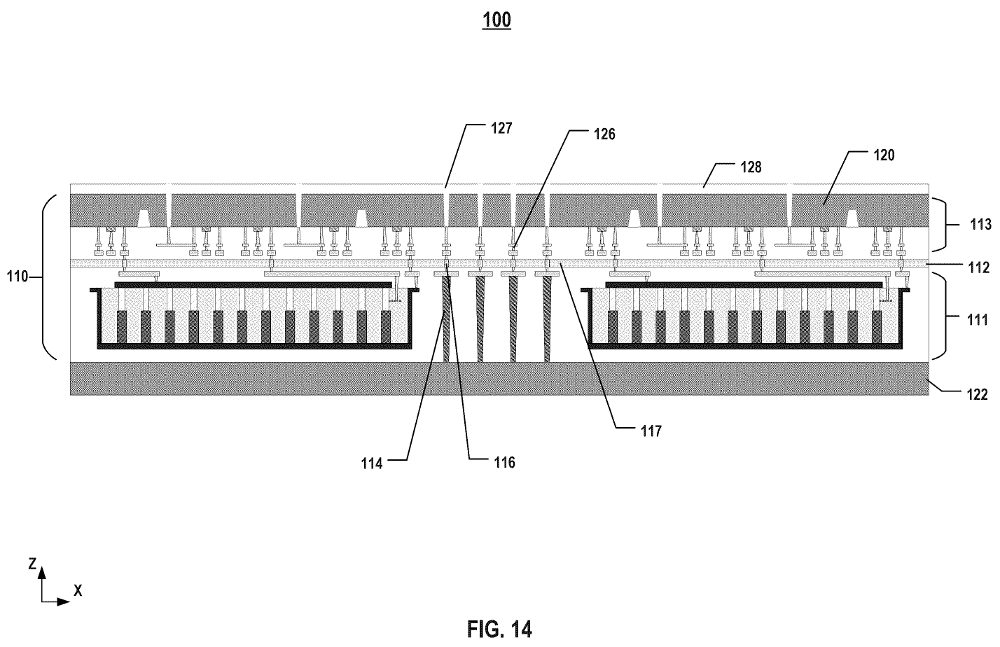

As shown in FIG. 14, a buffer dielectric layer 128 is formed on the backside of the first substrate 120. In some implementations, the buffer dielectric layer 128 may include silicon oxide. Then, a contact hole 127 is formed in the first substrate 120. In some implementations, the contact hole 127 penetrates the first substrate 120 to expose the redistribution structures 126. In some implementations, because the etching operation used to form the contact hole 127 is performed from the backside of the first substrate 120, the contact hole 127 may have a larger size at the upper portion and a smaller size at the lower portion.

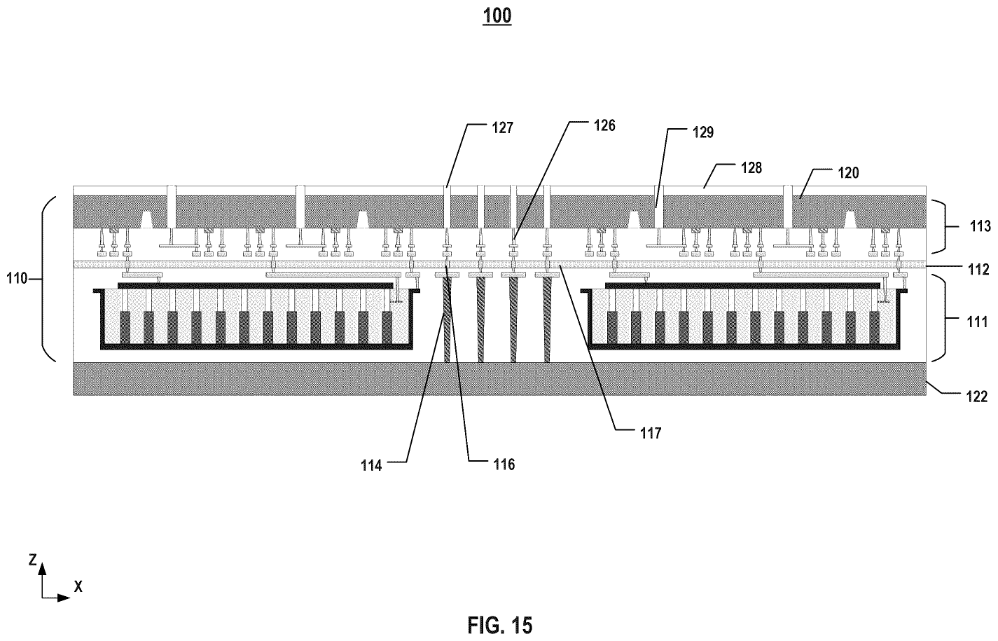

As shown in FIG. 15, a liner dielectric layer 129 is formed on the sidewalls of the contact hole 127. In some implementations, the liner dielectric layer 129 may include silicon oxide. In some implementations, after forming the liner dielectric layer on the sidewalls of contact hole 127, an etching operation may be performed to clean the bottom of contact hole 127 and expose the redistribution structures 126.

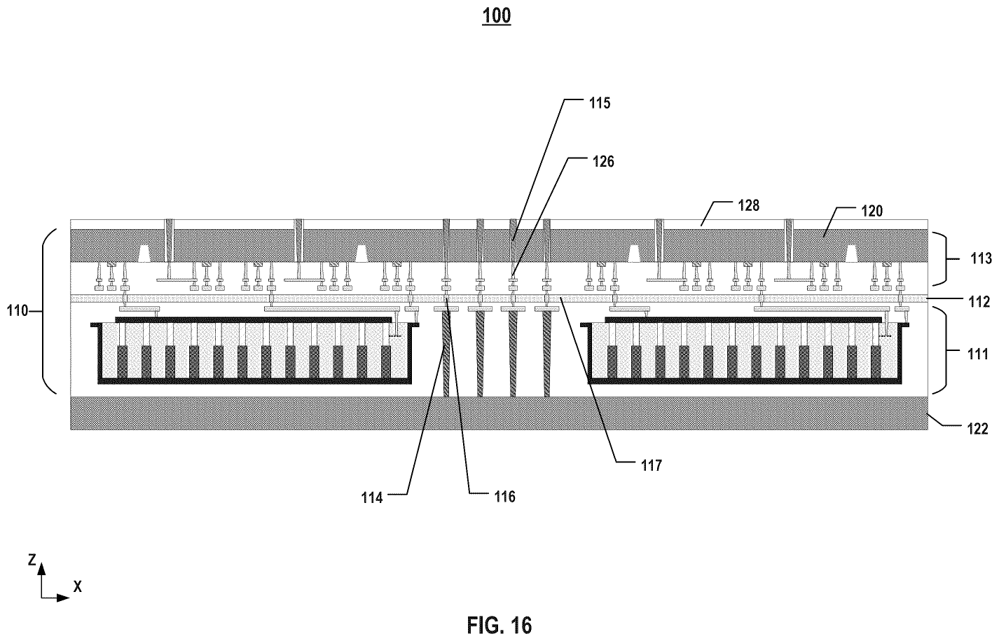

As shown in FIG. 16, the second contact structure 115 is formed in the contact hole 127 extending along the Z-direction. In some implementations, the second contact structure 115 is in direct contact with the redistribution structure 126. In some implementations, the second contact structure 115, the redistribution structures 126, the metal structure 116, and the first contact structure 114 form a vertical conductive path along the Z-direction. In some implementations, the second contact structure 115, the redistribution structures 126, the metal structure 116, and the first contact structure 114 include the conductive material, e.g., Cu or W. In some implementations, a planarization operation may be further performed on the first semiconductor chip 110 after forming the second contact structure 115.

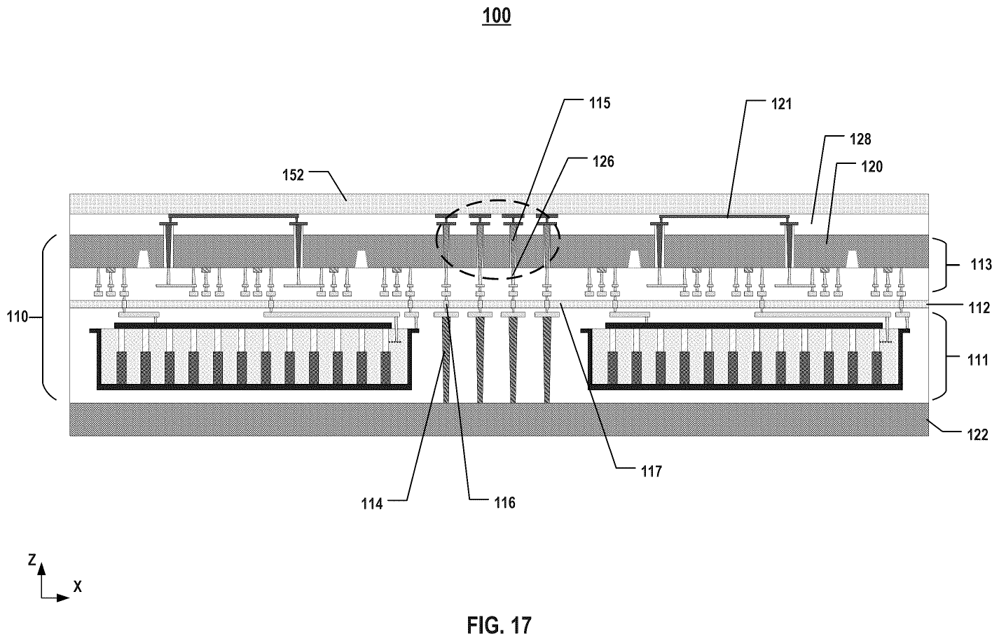

As shown in FIG. 17, the backside wiring structure 121 is formed on the backside of the first substrate 120. Because the periphery devices, e.g., CMOS, are formed on one side of the first substrate 120, and the backside wiring structure 121 is formed on the opposite side of the first substrate 120, the power supply efficiency can be improved, and the IR delay can be reduced. In some implementations, the dielectric bonding material 152 is then formed on the first periphery structure 113. In some implementations, the dielectric bonding material 152 includes a dielectric bonding material, e.g., nitrogen-doped silicon carbide (NDC).

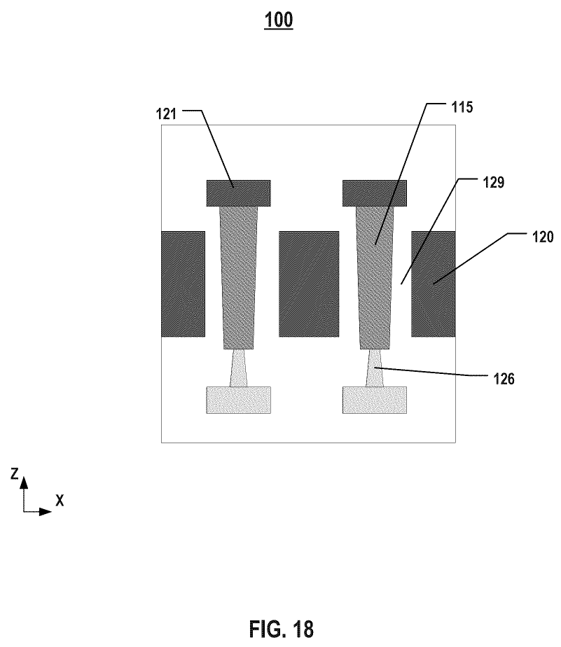

FIG. 18 shows a partially enlarged view of the dotted line area in FIG. 17. Because the etching operation used to form the contact hole 127 is performed from the backside of the first substrate 120, the contact hole 127 may have a larger size at the upper portion and a smaller size at the lower portion. As shown in FIG. 18, after forming the second contact structure 115 in contact hole 127, the second contact structure 115 may also have a larger size at the upper portion and a smaller size at the lower portion. The second contact structure 115 penetrates the first substrate 120 along the Z-direction. In some implementations, the length of the second contact structure 115 is greater than the thickness of the first substrate 120. In some implementations, because the liner dielectric layer 129 is formed on the sidewalls of the contact hole 127 before filling the second contact structure 115, the second contact structure 115 and the first substrate 120 are separated by the liner dielectric layer 129 after forming the second contact structure 115.

In some implementations, the second contact structure 115 may be formed in the first periphery structure 113 before the bonding of the first memory structure 111 and the first periphery structure 113, as shown in FIGS. 19-26.

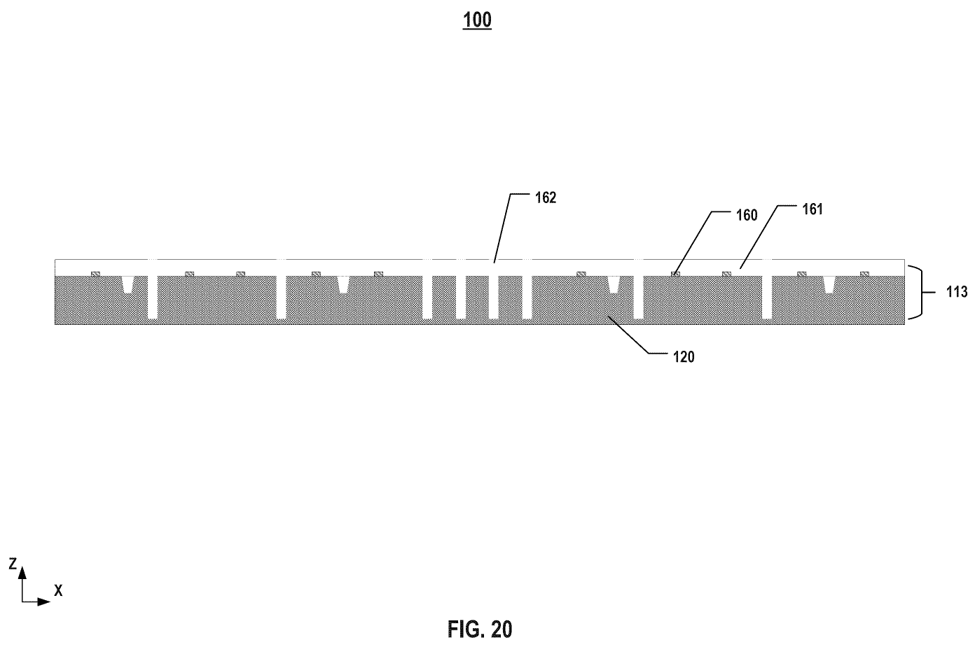

As shown in FIG. 19, the periphery devices 160, e.g., CMOS, are formed on the first substrate 120, and a dielectric layer 161 is formed on the periphery devices 160 and the first substrate 120. As shown in FIG. 20, a contact hole 162 is formed in the dielectric layer 161 and the first substrate 120. In some implementations, the contact hole 162 extends in the dielectric layer 161 and the first substrate 120 along the Z-direction. In some implementations, the contact hole 162 penetrates the dielectric layer 161 and extends into the first substrate 120.

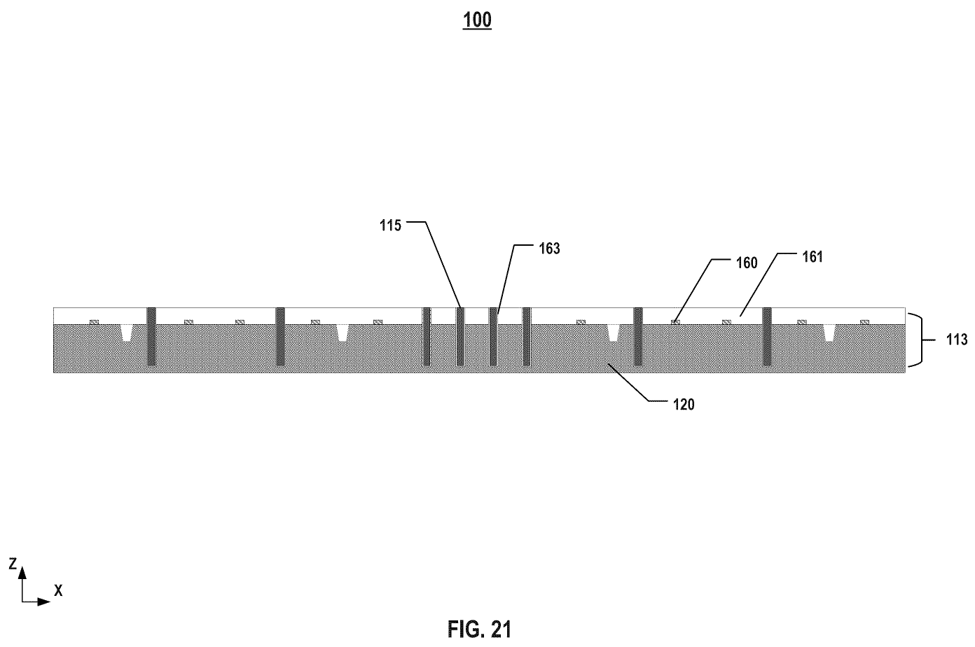

Then, as shown in FIG. 21, a liner dielectric layer 163 is formed on the sidewalls of the contact hole 162, and the second contact structure 115 is formed in the contact hole 162. In some implementations, the second contact structure 115 includes the conductive material, e.g., Cu or W. In some implementations, a planarization operation may be further performed on the second contact structure 115 and the dielectric layer 161 after forming the second contact structure 115.

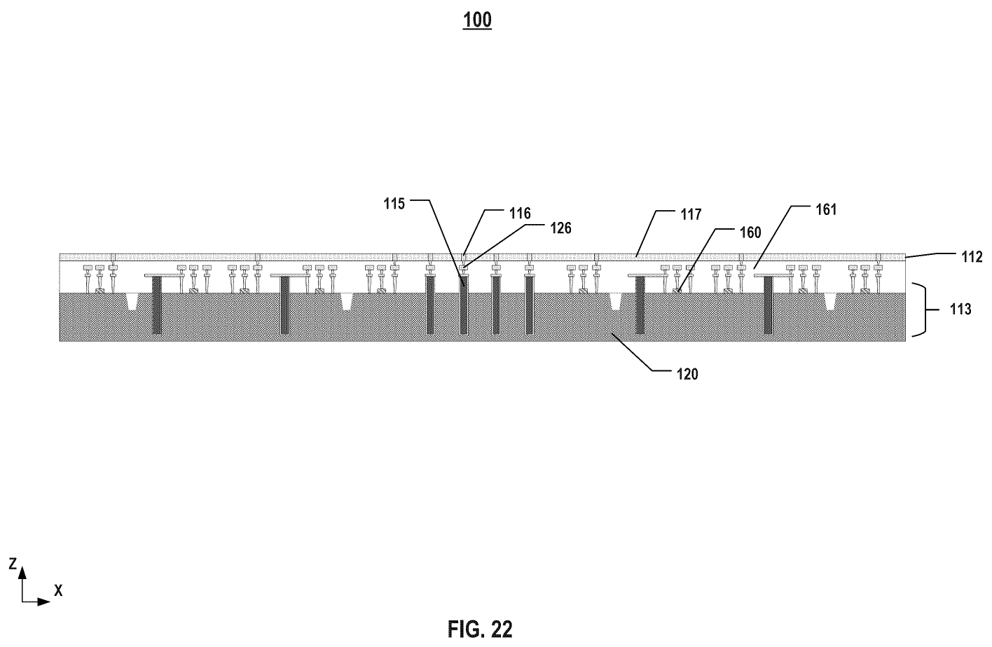

As shown in FIG. 22, the redistribution structure 126 is formed on the second contact structure 115, and the first coupling layer 112 is formed on the redistribution structure 126. The first coupling layer 112 includes the metal structure 116 in contact with at least the redistribution structure 126 and the dielectric bonding material 117.

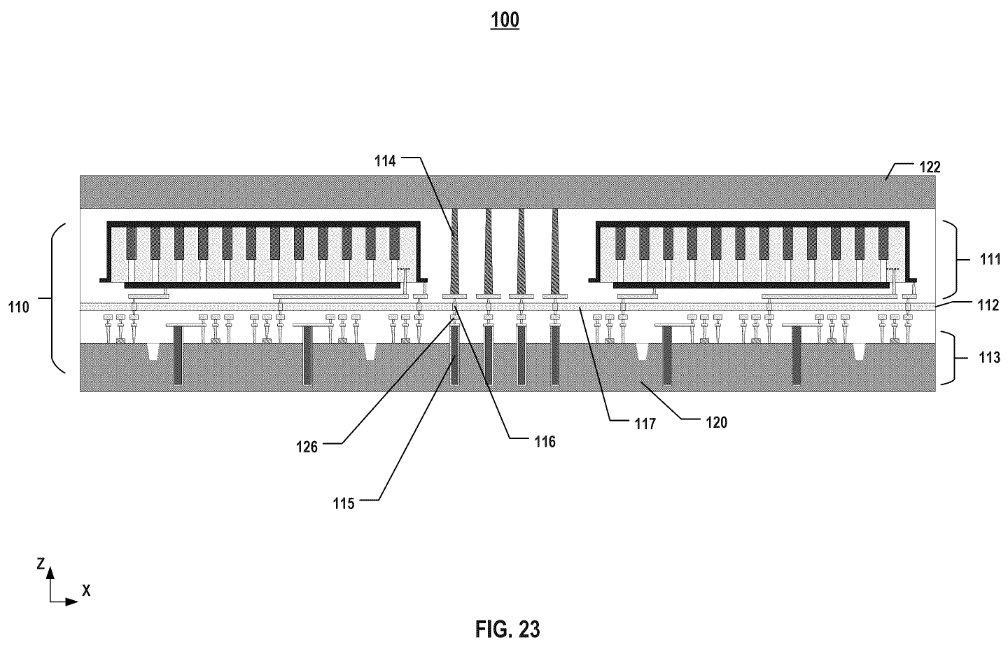

As shown in FIG. 23, the first memory structure 111 and the carrier substrate 122 in FIG. 11 are flipped over and bonded to the first periphery structure 113 through the first coupling layer 112. The first coupling layer 112 includes the metal structure 116 in contact with at least the first contact structure 114 and the dielectric bonding material 117. In some implementations, the second contact structure 115, the redistribution structures 126, the metal structure 116, and the first contact structure 114 form a vertical conductive path along the Z-direction. In some implementations, the second contact structure 115, the redistribution structures 126, the metal structure 116, and the first contact structure 114 include the conductive material, e.g., Cu or W. In some implementations, the dielectric bonding material 117 includes a dielectric bonding material, e.g., nitrogen-doped silicon carbide (NDC).

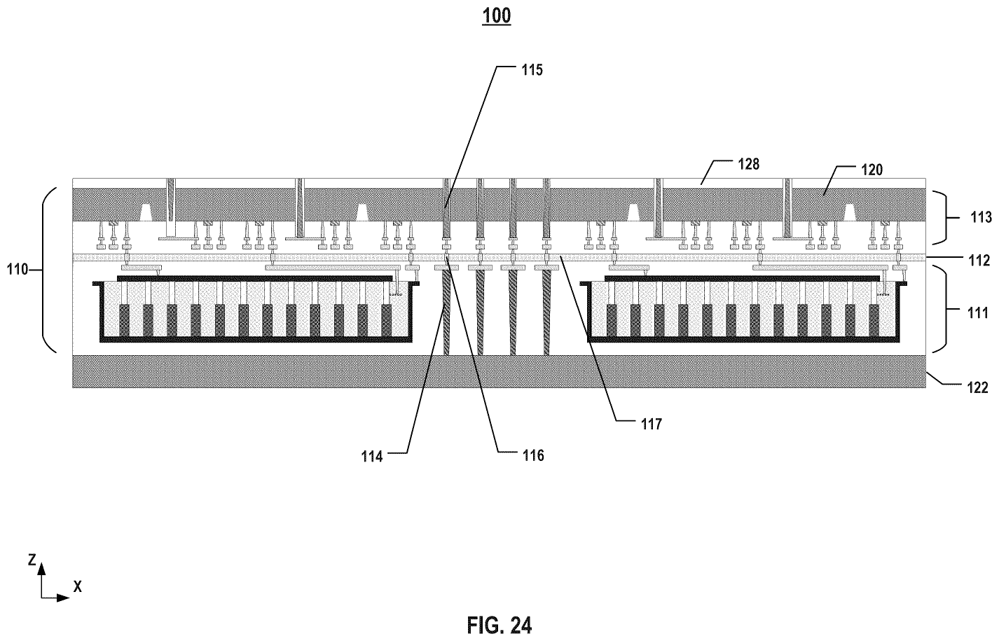

As shown in FIG. 24, the first semiconductor chip 110 is flipped over to perform operations on the backside of the first substrate 120. A thinning operation is performed to reduce the thickness of the first substrate 120. In some implementations, the thinning operation includes the silicon wafer back grinding operation and the chemical mechanical planarization (CMP) operation. In some implementations, after performing the thinning operation, an etching operation may be performed to remove a portion of the first substrate 120 and keep the second contact structure 115. In some implementations, the first substrate 120, e.g., a silicon wafer, may be partially removed by using the wet etching process. Then, the buffer dielectric layer 128 is formed on the backside of the first substrate 120. In some implementations, the buffer dielectric layer 128 may include silicon oxide. In some implementations, a planarization operation may be further performed on the buffer dielectric layer 128.

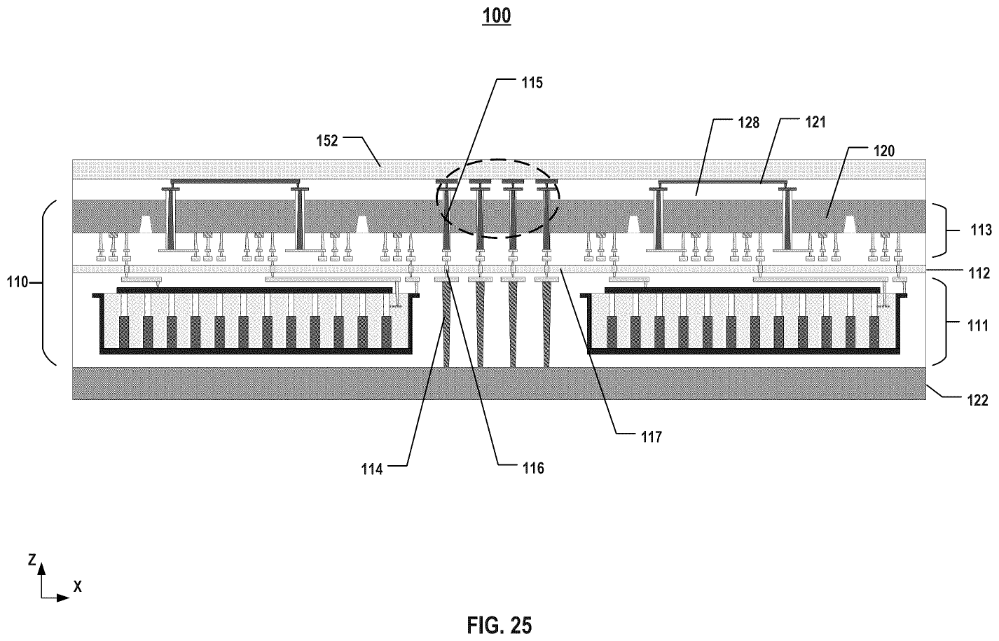

As shown in FIG. 25, the backside wiring structure 121 is formed on the backside of the first substrate 120. Because the periphery devices, e.g., CMOS, are formed on one side of the first substrate 120, and the backside wiring structure 121 is formed on the opposite side of the first substrate 120, the power supply efficiency can be improved, and the IR delay can be reduced. In some implementations, the dielectric bonding material 152 is then formed on the first periphery structure 113. In some implementations, the dielectric bonding material 152 includes a dielectric bonding material, e.g., nitrogen-doped silicon carbide (NDC).

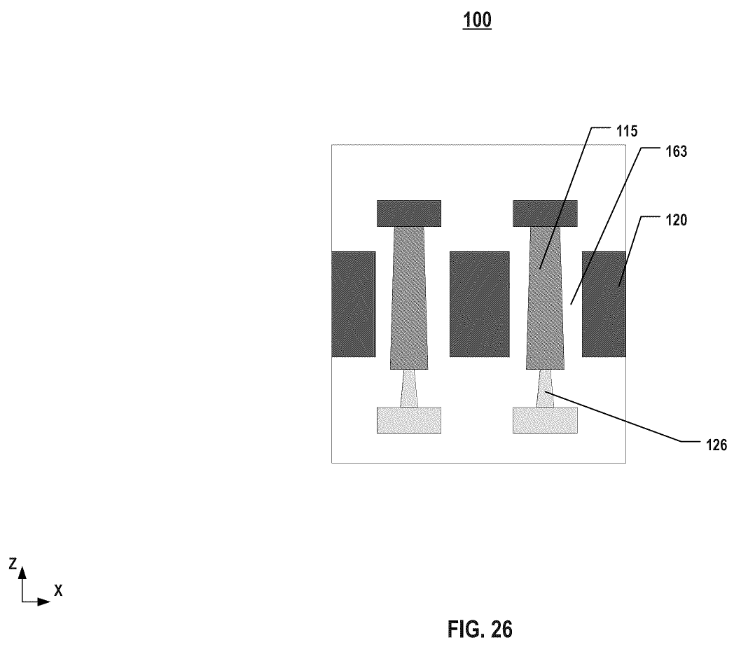

FIG. 26 shows a partially enlarged view of the dotted line area in FIG. 25. Because the etching operation used to form contact hole 127 is performed from the frontside of the first substrate 120, contact hole 162 may have a larger size at the lower portion (near the frontside) and a smaller size at the upper portion (neat the backside). As shown in FIG. 26, after forming the second contact structure 115 in contact hole 162, the second contact structure 115 may also have a larger size at the lower portion and a smaller size at the upper portion. The second contact structure 115 penetrates the first substrate 120 along the Z-direction. In some implementations, the length of the second contact structure 115 is greater than the thickness of the first substrate 120. In some implementations, because the liner dielectric layer 163 is formed on the sidewalls of the contact hole 162 before filling the second contact structure 115, the second contact structure 115 and the first substrate 120 are separated by the liner dielectric layer 163 after forming the second contact structure 115.

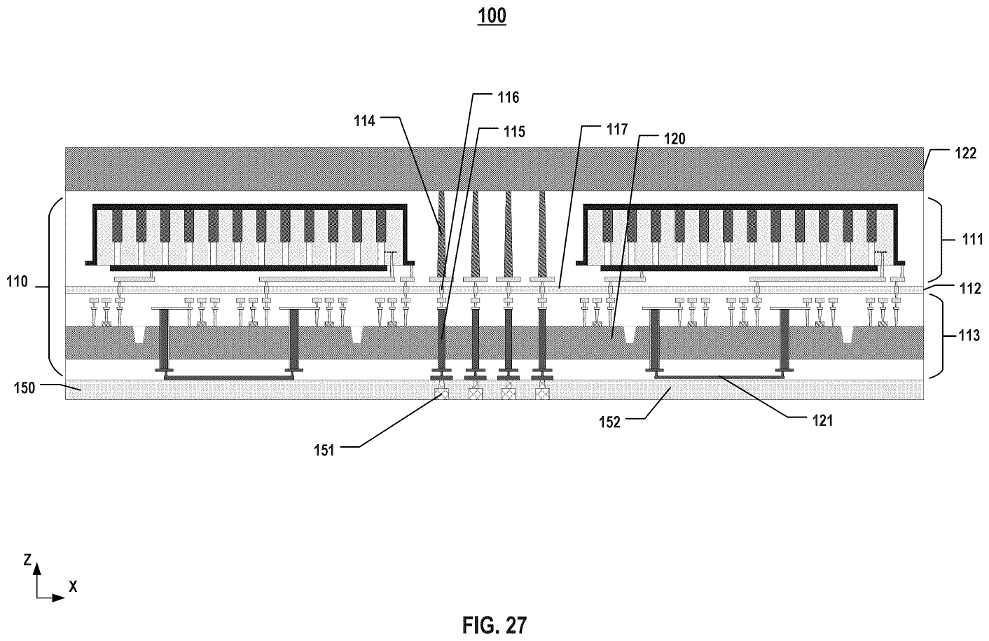

As shown in FIG. 27, after the first semiconductor chip 110 is formed, the chip-to-chip bonding layer 150 is formed on the first semiconductor chip 110. The chip-to-chip bonding layer 150 includes a hybrid dielectric-to-dielectric and metal-to-metal bonding layer. In some implementations, the chip-to-chip bonding layer 150 includes the metal structure 151 and the dielectric bonding material 152. In some implementations, the metal structure 151 includes a conductive material, e.g., Cu or W. In some implementations, the dielectric bonding material 152 includes a dielectric bonding material, e.g., nitrogen-doped silicon carbide (NDC). In some implementations, the metal structure 151 penetrates the dielectric bonding material 152, e.g., the nitrogen-doped silicon carbide (NDC) layer. In some implementations, the metal structure 151 extends along the z-direction in the dielectric bonding material 152.

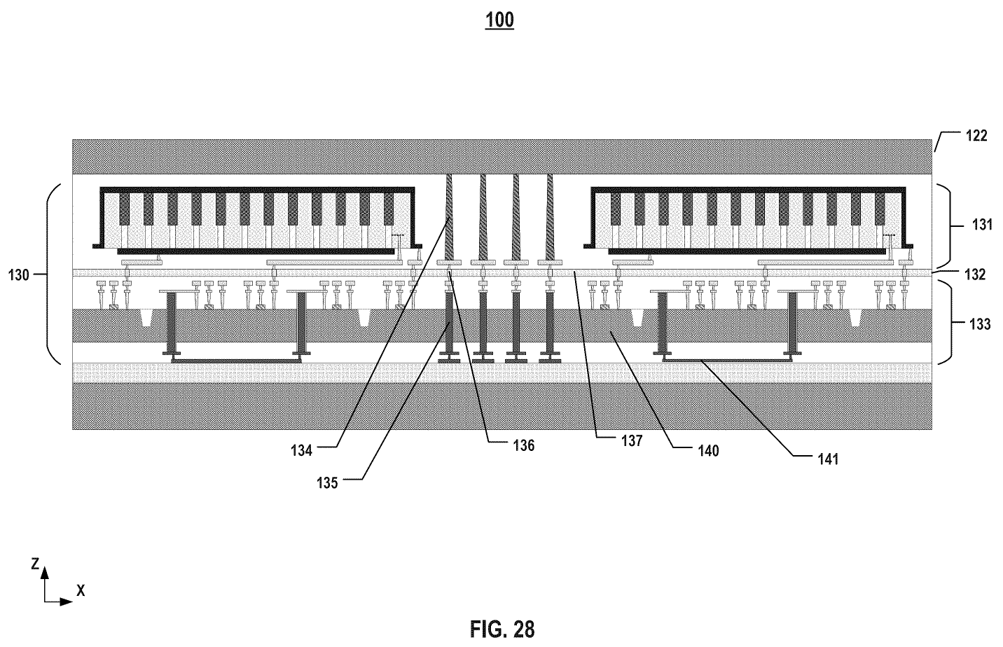

As shown in FIG. 28 and operation 3404 in FIG. 34, the second semiconductor chip 130 is formed. The second semiconductor chip 130 includes the second memory structure 131 having the third contact structure 134 extending along the Z-direction and the second periphery structure 133 having the fourth contact structure 135 extending along the Z-direction. In some implementations, the process of forming the second semiconductor chip 130 is similar to the process of forming the first semiconductor chip 110. The operations explained in FIGS. 6-26 may also be applied to the formation of the second semiconductor chip 130.

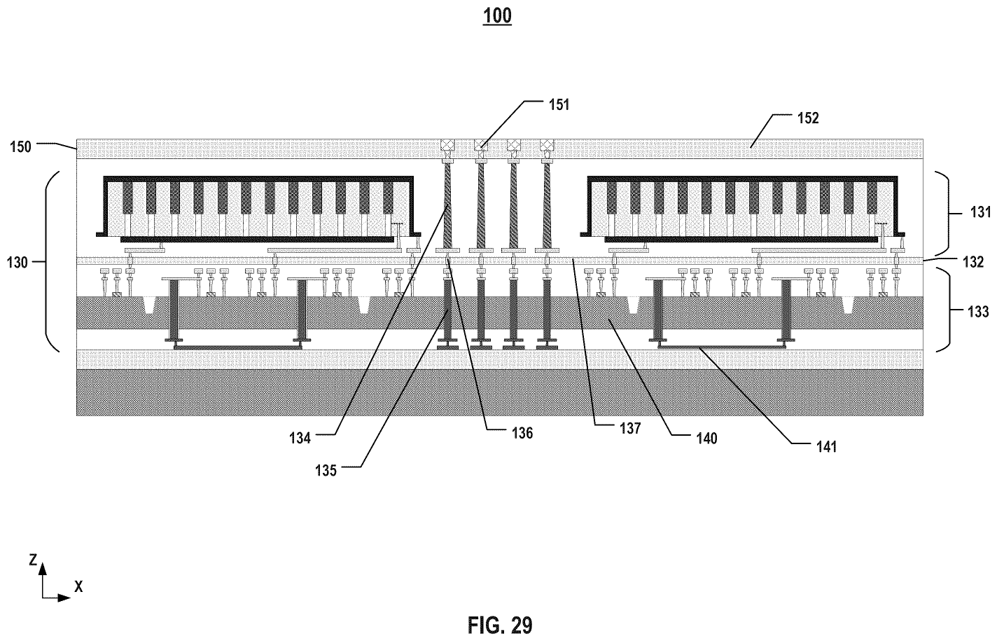

As shown in FIG. 29, the carrier substrate 122 is removed, and the chip-to-chip bonding layer 150 is formed on the second semiconductor chip 130. The chip-to-chip bonding layer 150 includes a hybrid dielectric-to-dielectric and metal-to-metal bonding layer. It is noted that the chip-to-chip bonding layer 150 formed on the first semiconductor chip 110 in FIG. 27 and the chip-to-chip bonding layer 150 formed on the second semiconductor chip 130 in FIG. 29 may have a similar structure and will be bonded in a later process.

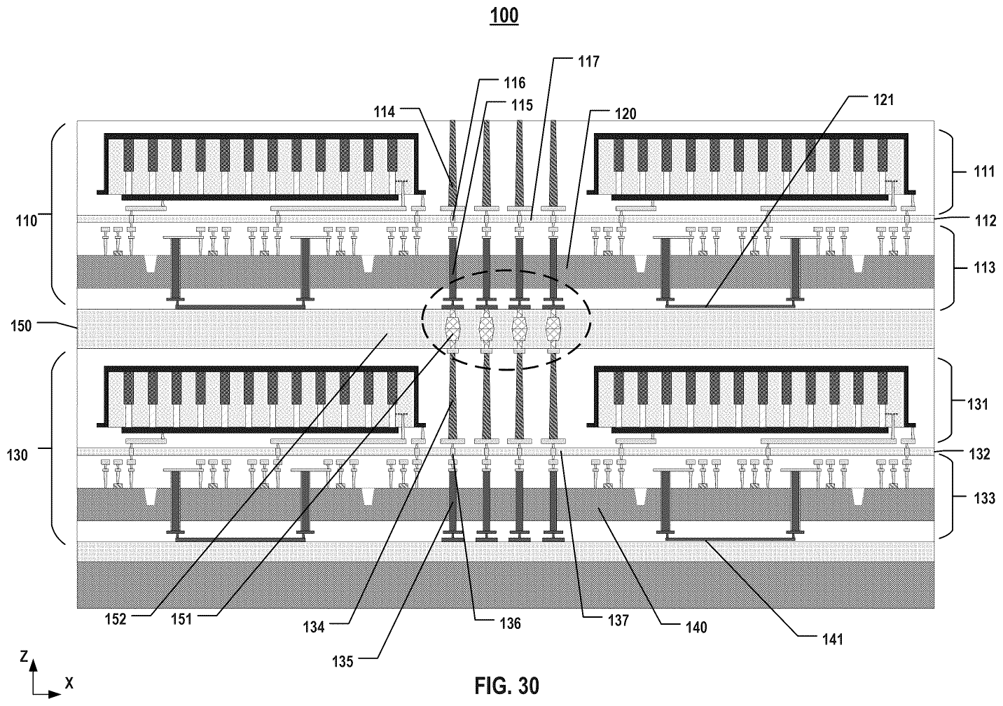

As shown in FIG. 30 and operation 3406 in FIG. 34, the first semiconductor chip 110 and the second semiconductor chip 130 are bonded through the chip-to-chip bonding layer 150. In some implementations, the chip-to-chip bonding layer 150 includes the first hybrid dielectric-to-dielectric and metal-to-metal bonding layer. In some implementations, the chip-to-chip bonding layer 150 includes the metal structure 151 and the dielectric bonding material 152. In some implementations, the metal structure 151 includes a conductive material, e.g., Cu or W. In some implementations, the dielectric bonding material 152 includes a dielectric bonding material, e.g., nitrogen-doped silicon carbide (NDC). In some implementations, the metal structure 151 penetrates the dielectric bonding material 152, e.g., the nitrogen-doped silicon carbide (NDC) layer. In some implementations, the metal structure 151 extends along the z-direction in the dielectric bonding material 152.

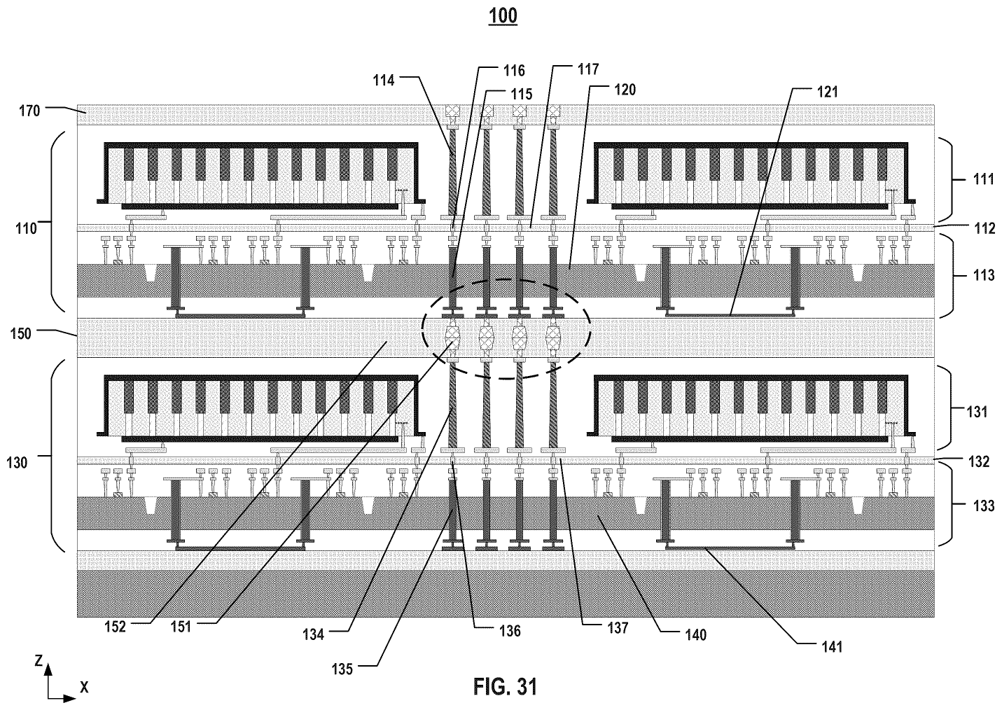

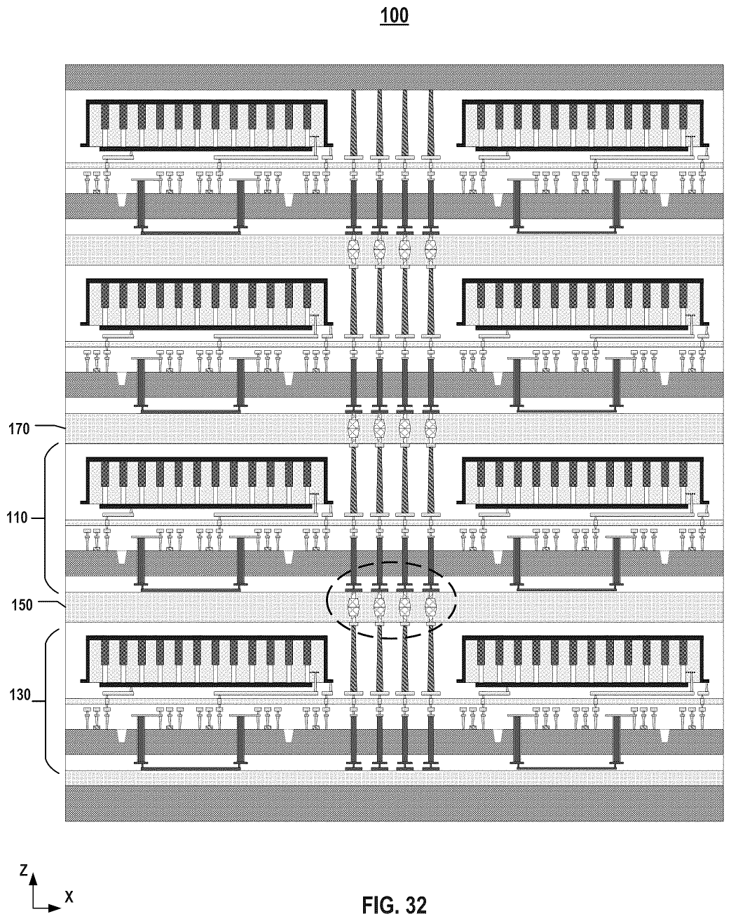

As shown in FIG. 31, a chip-to-chip bonding layer 170 may be further formed on the first semiconductor chip 110, and more semiconductor chips may be stacked on the first semiconductor chip 110 through the chip-to-chip bonding layer 170. As shown in FIG. 32, multiple semiconductor chips are stacked and bonded through the chip-to-chip bonding layer, which is similar to the operations of bonding the first semiconductor chip 110 and the second semiconductor chip 130 explained above.

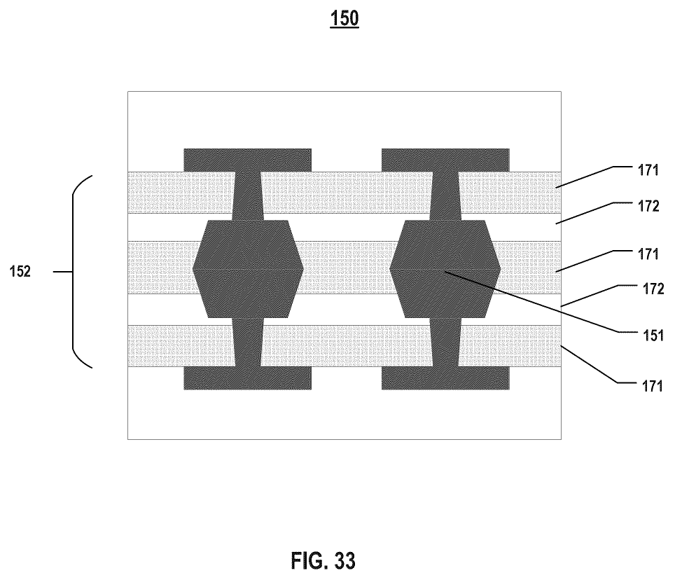

FIG. 33 shows a partially enlarged view of the dotted line area in FIGS. 30, 31, and 32. In some implementations, the dielectric bonding material 152 may be formed by multiple dielectric bonding layers. In some implementations, the dielectric bonding material 152 may include multiple first bonding layers 171 and multiple second bonding layers 172. In some implementations, the first bonding layers 171 and the second bonding layers 172 are interlaced. In some implementations, the first bonding layers 171 include nitrogen-doped silicon carbide (NDC), and the second bonding layers 172 include silicon oxide. In some implementations, the metal structure 151 extends along the z-direction in the interlaced first bonding layers 171 and second bonding layers 172.

By forming the first contact structure 114 and/or the third contact structure 134 in the array wafer, forming the second contact structure 115 and/or the fourth contact structure 135 in the CMOS wafer, and thinning the backside of the CMOS wafer, the TSVs could be drawn out to form a connection path that vertically runs through the stack of memory chips. In addition, the present disclosure can also realize power supply from the backside of the CMOS wafer, improving power supply efficiency and reducing IR delay. Since the substrate of the vertical transistors array only has a supporting function, it is easier to thin during the process of stacking multiple memory chips, which is beneficial to maintaining the flatness of the chips, reducing the total thickness of the device, and making it easier to stack a higher number of layers.

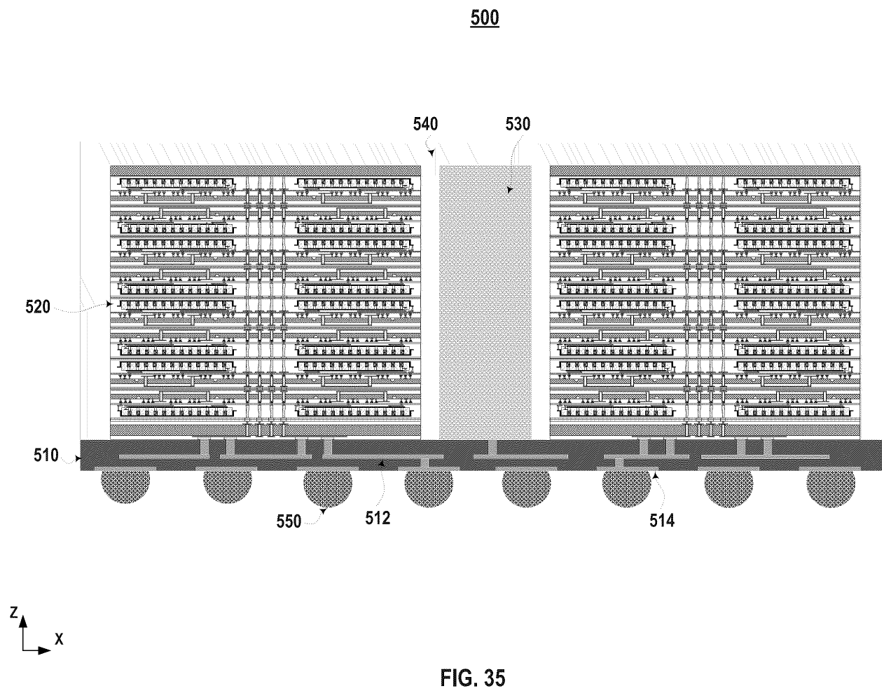

FIG. 35 illustrates a side view of a cross-section of a memory device 500, according to some implementations of the present disclosure. Memory device 500 can be a DRAM device. As shown in FIG. 35, the memory device 500 can be a chip packing structure including a base substrate 510, one or more die stacks 520 and a memory control circuit 530 on a first side of the base substrate 510, a mold compound layer 540 fully covering the one or more die stacks 520 and the memory control circuit 530, and a ball grid array (BGA) 550 on a second side of the base substrate 510 opposite to the first side. In some implementations, the die stack 520 may be the semiconductor structure 100 described above.

The base substrate 510 can be any suitable semiconductor substrate having any suitable structure, such as a monocrystalline single-layer substrate, a polycrystalline silicon (polysilicon) single-layer substrate, a polysilicon and metal multi-layer substrate, etc. The base substrate 510 can include conductive wiring structures 512 embedded therein. The conductive wiring structures 512 can include any suitable conductive interconnection structures, such as conductive vias and patterned conductive layers, etc. The base substrate 510 can further include an array of ball pads 514 on a bottom surface to accept the BGA 550 for both electrical connections and/or mechanically fasten connections. The conductive wiring structures 512 and the array of ball pads 514 can include any suitable conductive materials, such as copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), graphite, carbon black, combinations thereof, and/or other materials known to those skilled in the art.

In some implementations, the one or more die stacks 520 can include one or more portions of the semiconductor structure 100, as described above in detail. The one or more die stacks 520 can be attached to the base substrate 510 by an adhesive film (not shown). The adhesive film can be any suitable die-attached film (DAF).

In some implementations, the memory control circuit 530 is coupled to the one or more die stacks 520 and is configured to control and coordinate the one or more die stacks 520, according to some implementations. The memory control circuit 530 can be configured to coordinate the one or more die stacks 520 and to control operations of multiple memory cell arrays within the one or more die stacks 520. In some implementations, the memory control circuit 530 can also be configured to manage various functions with respect to the data stored or to be stored in the one or more die stacks 520 including, but not limited to refresh and timing control, command/request translation, buffer and schedule, and power management. In some implementations, the memory control circuit 530 is further configured to determine the maximum memory capacity and speed, memory particle data depth and data width, and other important parameters.

In some implementations, a plurality of signal wires (not shown) can be electrically connected between the plurality of bond pads of the one or more die stacks 520, the memory control circuit 530, and the conductive wiring structures 512. As such, the one or more die stacks 520 and/or the memory control circuit 530 can be coupled with the BGA 550 and connected to an external device, such as a printed circuit board (PCB). In some implementations, the BGA 550 can include a plurality of solder balls on the bottom surface of the base substrate 510 and mechanically connected to the ball pads 514. That is, the solder balls are configured for electrically connecting the memory device 500 to a PCB to provide transmission of electric signals between a circuit on the PCB and the one or more die stacks 520 and/or memory control circuit 530 of the memory device 500. In some implementations, the solder balls can comprise any suitable metal material, such as Aluminum (Al), Antimony (Sb), Arsenic (As), Bismuth (Bi), Cadmium (Cd), Co, Cu, Ni, Au, Ag, Indium (In), Iron (Fc), Lead (Pb), Phosphorus (P), Tin (Sn), Sulfur(S), Zinc (Zn), Germanium (Ge), etc., and any suitable alloy thereof.

As shown in FIG. 35, the memory device 500 can further include a mold compound layer 540 on the base substrate 510 to fully cover the one or more die stacks 520 and memory control circuit 530. In some implementations, the mold compound layer 540 can be a thermally curable epoxy mold compound or a thermally curable epoxy mold resin. For example, the mold compound layer 540 comprises an inorganic filler (for example, silica), an epoxy resin, a curing agent, a flame retardant, a curing promoter, a release agent, and any other suitable components as known to those skilled in the art.

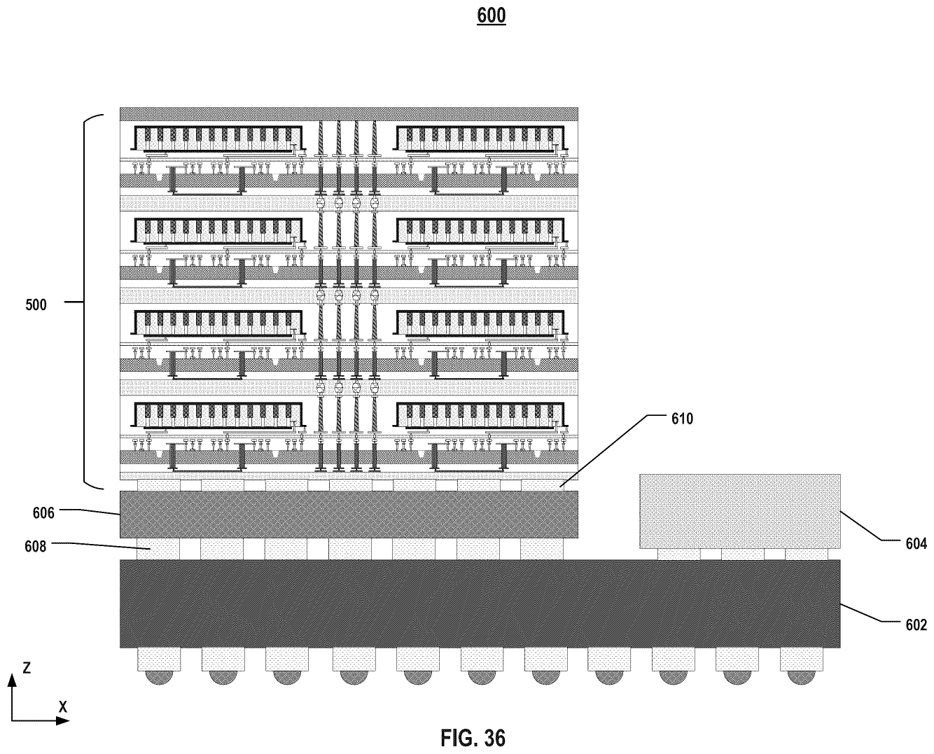

FIG. 36 illustrates a schematic side view of a cross-section of a memory system 600, according to some implementations of the present disclosure. The memory system 600 includes an interposer 602, the memory device 500 disposed on the interposer 602, a base die 606 disposed between the interposer 602 and the memory device 500, and a computing die 604 disposed on the interposer 602. In some implementations, the base die 606 is configured to control the memory device 500, and the base die 606, and the computing die 604 are integrated on the interposer 602 along the X-direction perpendicular to the Z-direction. As shown in FIG. 36, the semiconductor chips and the base die 606 are stacked (e.g., sequentially) along the Z-direction. The base die 606 and the computing die 604 are integrated on different positions of the interposer 602 along the X-direction. In some implementations, the memory device 500 may be boned to the base die 606 through a bonding layer 610. In some implementations, the bonding layer 610 may be the BGA 550 in FIG. 35.

In some implementations, the base die 606 includes a control circuitry that is configured to control the memory device 500. The base die 606 is bonded to the interposer 602 through a plurality of bump structures 608. The base die 606 may be coupled to the computing die 604 through the interposer 602. The interposer 602 may have the conductive terminals and the wirings internally formed in the interposer 602, and the base die 606 may be coupled to the computing die 604 through the conductive terminals and the internal wirings of the interposer 602. It is understood that in practice, the base die 606, the computing die 604, and the interposer 602 can be integrated together using any suitable packaging technology including, for example, Chip-on-Wafer-on-Substrate (CoWoS).

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A semiconductor structure, comprising:
a first semiconductor chip comprising:
a first memory structure comprising a first contact structure extending along a first direction; and
a first periphery structure disposed on a first substrate, the first periphery structure in contact with the first memory structure and comprising a second contact structure extending along the first direction; and
a second semiconductor chip stacking with the first semiconductor chip along the first direction,
wherein the second semiconductor chip is bonded to the first semiconductor chip through a chip-to-chip bonding layer; and
the first contact structure and the second contact structure are coupled through a first coupling layer.

2. The semiconductor structure of claim 1, wherein the second semiconductor chip comprises:
a second memory structure comprising a third contact structure extending along the first direction; and
a second periphery structure disposed on a second substrate, the second periphery structure in contact with the second memory structure and comprising a fourth contact structure extending along the first direction.

3. The semiconductor structure of claim 2, wherein the third contact structure and the fourth contact structure are coupled through a second coupling layer.

4. The semiconductor structure of claim 3, wherein the chip-to-chip bonding layer comprises a first hybrid dielectric-to-dielectric and metal-to-metal bonding layer.

5. The semiconductor structure of claim 4, wherein the first hybrid dielectric-to-dielectric and metal-to-metal bonding layer comprises a first nitrogen-doped silicon carbide layer and a first metal structure.

6. The semiconductor structure of claim 5, wherein the second contact structure and the third contact structure are coupled through the first metal structure, and the first metal structure penetrates the first nitrogen-doped silicon carbide layer.

7. The semiconductor structure of claim 2, wherein the second memory structure of the second semiconductor chip is bonded to the first periphery structure of the first semiconductor chip.

8. The semiconductor structure of claim 7, wherein the first memory structure and the second memory structure are separated by the first periphery structure.

9. The semiconductor structure of claim 7, wherein the second contact structure penetrates the first substrate, and the fourth contact structure penetrates the second substrate.

10. The semiconductor structure of claim 1, wherein the first coupling layer comprises a second hybrid dielectric-to-dielectric and metal-to-metal bonding layer.

11. The semiconductor structure of claim 10, wherein the first contact structure and the second contact structure are in contact through a second metal structure in the second hybrid dielectric-to-dielectric and metal-to-metal bonding layer.

12. The semiconductor structure of claim 3, wherein the second coupling layer comprises a third hybrid dielectric-to-dielectric and metal-to-metal bonding layer.

13. The semiconductor structure of claim 12, wherein the third contact structure and the fourth contact structure are in contact through a third metal structure in the third hybrid dielectric-to-dielectric and metal-to-metal bonding layer.

14. The semiconductor structure of claim 2, further comprising:
a logic die disposed below the second semiconductor chip configured to control the semiconductor structure.

15. The semiconductor structure of claim 14, wherein the logic die comprises a fifth contact structure extending along the first direction, and the logic die is bonded to the second semiconductor chip through a fourth hybrid dielectric-to-dielectric and metal-to-metal bonding layer.

16. The semiconductor structure of claim 15, wherein the fifth contact structure is in contact with the fourth contact structure through the fourth hybrid dielectric-to-dielectric and metal-to-metal bonding layer.

17. The semiconductor structure of claim 16, further comprising:
a bonding pad disposed below the logic die in contact with the fifth contact structure.

18. A semiconductor structure, comprising:
a first semiconductor chip comprising:
a first memory structure comprising a first vertical transistor extending in a first direction and a first storage unit in contact with the first vertical transistor; and
a first periphery structure disposed on a first substrate, the first periphery structure in contact with the first memory structure; and
a second semiconductor chip stacking with the first semiconductor chip along the first direction, the second semiconductor chip comprising:
a second memory structure comprising a second vertical transistor extending in the first direction and a second storage unit in contact with the second vertical transistor; and
a second periphery structure disposed on a second substrate, the second periphery structure in contact with the second memory structure,
wherein the second semiconductor chip is bonded to the first semiconductor chip through a first hybrid dielectric-to-dielectric and metal-to-metal bonding layer.

19. The semiconductor structure of claim 18, wherein the first hybrid dielectric-to-dielectric and metal-to-metal bonding layer comprises a first carbon-doped silicon nitride layer and a first metal structure.

20. A method of forming a semiconductor structure, comprising:
forming a first semiconductor chip comprising a first memory structure having a first contact structure extending along a first direction and a first periphery structure having a second contact structure extending along the first direction;
forming a second semiconductor chip comprising a second memory structure having a third contact structure extending along the first direction and a second periphery structure having a fourth contact structure extending along the first direction; and
bonding the first semiconductor chip and the second semiconductor chip through a first hybrid dielectric-to-dielectric and metal-to-metal bonding layer.
